(19) United States
(12) Patent Application Publication
(10) Pub. No.: US 2026/0038556 A1
(43) Pub. Date: Feb. 5, 2026

(54) RETENTION AWARE REFRESH OPERATIONS

(71) Applicant: Micron Technology, Inc., Boise, ID (US)

(72) Inventors: Bryan David Kerstetter, Kuna, ID (US); Ben Wiggins, Boise, ID (US)

(21) Appl. No.: 19/270,072

(22) Filed: Jul. 15, 2025

Related U.S. Application Data
(60) Provisional application No. 63/677,326, filed on Jul. 30, 2024.

(51) Int. Cl. G11C 11/406

(52) U.S. Cl. CPC G11C 11/406

(57) ABSTRACT

Methods, systems, and devices for retention aware refresh operations are described. A memory system supporting retention aware refresh may involve a first counter associated with a first set of memory cells and a second set of memory cells, and a second counter associated with the second set of memory cells, where the second set of memory cells may be associated with a set of memory elements. The memory system may further include a memory element selection component configured to select at least a subset of the second set of memory cells based on the second counter, and an address selection component configured to select a first address output by the first counter or a second address output by the memory element selection component for a refresh operation. Multiple second sets of memory cells, memory element selection components, and address selection components also may be included.

### CROSS REFERENCE

The present Application for Patent claims priority to U.S. Patent Application No. 63/677,326 by Kerstetter et al., entitled “RETENTION AWARE REFRESH OPERATIONS,” filed Jul. 30, 2024, which is assigned to the assignee hereof, and which is expressly incorporated by reference in its entirety herein.

### TECHNICAL FIELD

The following relates to one or more systems for memory, including retention aware refresh operations.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports retention aware refresh operations in accordance with examples as disclosed herein.

FIG. 2 shows an example of a retention distribution chart that supports retention aware refresh operations in accordance with examples as disclosed herein.

FIG. 3 shows an example of a flow diagram that supports retention aware refresh operations in accordance with examples as disclosed herein.

FIG. 4 shows an example of a circuit diagram that supports retention aware refresh operations in accordance with examples as disclosed herein.

FIGS. 5A and 5B show examples of circuit diagrams that support retention aware refresh operations in accordance with examples as disclosed herein.

FIGS. 6A and 6B show examples of circuit diagrams that support retention aware refresh operations in accordance with examples as disclosed herein.

FIGS. 7A and 7B show examples of circuit diagrams that support retention aware refresh operations in accordance with examples as disclosed herein.

FIG. 8 shows an example of a circuit diagram that supports retention aware refresh operations in accordance with examples as disclosed herein.

FIGS. 9A and 9B show examples of a bank address diagram and a refresh assignment diagram that support retention aware refresh operations in accordance with examples as disclosed herein.

FIG. 10 shows a block diagram of a memory system that supports retention aware refresh operations in accordance with examples as disclosed herein.

FIG. 11 shows a flowchart illustrating a method or methods that support retention aware refresh operations in accordance with examples as disclosed herein.

### DETAILED DESCRIPTION

Some memory systems (e.g., dynamic random access memory (DRAM) systems) may support refresh operations for memory cells to prevent data loss due to leakage over time. Refresh operations may be performed at various intervals (e.g., various refresh intervals), where a refresh interval may be based on a lowest retention time (e.g., a time associated with retaining a charge in a memory cell), or refresh requirement time, of memory cells within an array. Refresh operations may be tracked using a global row counter, or column address strobe (CAS) before row address strobe (RAS) (CBR) counter, to refresh each of multiple CBR sets of memory cells (e.g., incrementally for each counter value), as well as a per-row counter, or a per row activation counter (PRAC). In some cases, a CBR set may represent a set of memory cells that are refreshed together. For example, each CBR counter value may be associated with a refresh address, and may result in a corresponding set of rows being refreshed together, where this set of rows refreshed together may represent a CBR set. In some cases, there may be a multitude of CBR sets, where a quantity of the CBR sets may be equivalent to a quantity of states associated with the CBR counter. In some cases, as memory density increases in device configurations, cell leakage may increase while cell capacitance (e.g., electrical capacitance) may be reduced, causing challenges in satisfying different refresh thresholds and parameters (e.g., defined refresh and timing parameters). For example, increased cell leakage and reduced cell capacitance may reduce a retention time for how long one or more memory cells is able to hold a charge before performing a refresh.

To support scaling and higher density memory configurations, some systems may increase a refresh rate, add error correction, or improve a sense margin. For example, to ensure proper data retention in weaker memory cells, a refresh requirement time (tREF), or time by which one or more cells in a device are required to be refreshed (e.g., a time by which all cells of a DRAM device must be refreshed), may be reduced for a memory system while a refresh rate may be increased (e.g., a refresh rate may be inversely proportional to (REF). However, increasing a refresh rate may increase power consumption, adding error correction may increase a die size (e.g., total die area to accommodate circuitry), and improving a sense margin may allow for an increase in tREF. Other systems may implement retention aware refresh, which may utilize a retention distribution for refresh operations, and may omit the use of refresh commands by implementing refresh interval tables, or may implement additional operations at a controller. An overhead associated with a controller of a memory system or host system may be related to refresh overhead. Some retention aware refresh schemes may increase refresh overhead. For example, refresh overhead may increase in some retention aware refresh schemes in which activate and precharge commands are used to perform refresh. In some examples, refresh overhead may be defined as a portion of time that read or write requests (e.g., of a system controller) cannot be fulfilled due to refresh, and may be expressed by different parameters, including by a refresh cycle time (tRFC) that may represent a time to perform a refresh cycle (e.g., activate to precharge time, tRC, if activate and precharge commands are used in place of a refresh command), or by a refresh interval (tREFI) that may represent an interval between refresh cycles (e.g., interval associated with activate and precharge commands dedicated to refresh if activate and precharge commands are used in place of a refresh command). Refresh overhead may also be proportional to read or write request latency. Further, other retention aware refresh schemes may still fail to meet different refresh parameters (e.g., defined tREF values, tREFI). Further, some retention aware refresh schemes may increase overhead and processing at a controller of a memory system or host system due to other factors unrelated to refresh overhead.

Techniques described herein may support circuitry and methods to accommodate weaker retention memory cells (e.g., memory cells with relatively low retention rates involving more frequent refresh operations), while adhering to refresh parameters and having relatively little die size impact. For example, a system may support low overhead retention aware refresh (LORAR). A LORAR scheme may involve identifying CBR sets that include memory cells with relatively weak retention characteristics, and may involve additional memory elements (e.g., non-volatile memory elements, volatile memory elements), such as fuses or latches, used for storing addresses corresponding to sets of weak retention memory cells. Sets including weak retention memory cells associated with such memory elements may be referred to as fuse CBR sets. For example, one or more memory elements, or fuses, may store a fuse CBR set address for a corresponding fuse CBR set. As the CBR counter increments across each of a total quantity of CBR sets, refresh operations may occur to refresh each CBR set. Such refresh operations may be referred to as a normal refresh operations. Further, additional refresh operations unrelated to the CBR counter may target fuse CBR sets, where such additional refresh operations may be referred to as fuse CBR set refresh operations. For example, for every X total refresh operations performed, a refresh operation may be performed for a fuse CBR set to ensure such cells retain data.

Additional refresh operations may involve a longer tREF for normal refresh operations, and a shorter tREF for fuse CBR set refresh operations. By enabling a longer tREF for normal refresh operations, refresh power may be reduced with a smaller die size impact compared to other retention aware refresh schemes, while supporting weaker retention cells with a lower tREF may increase a yield in manufacturing (as such cells may otherwise be repaired). In some cases, a concurrent LORAR scheme may be implemented to increase a quantity of fuse CBR sets that may be refreshed (e.g., at a time). For example, instead of refreshing a fuse CBR set across each bank of one or more dies, individual logic circuitry may be included in each bank to increase a quantity of fuse CBR sets refreshed within a time period, further increasing yield, allowing even lower short tREF for weak memory cells, granting decreased overhead, and improving compatibility and die area savings. Further examples may include logic circuitry for refreshing a quantity of banks (e.g., at every K quantity of banks), while some examples may include individual logic within multiple portions of a bank for performing refresh operations for each portion (e.g., for refreshing a subset of memory cells of the bank corresponding to a fuse CBR set). Further, any combination of circuitry for refreshing any set or subset of memory cells and banks may be considered for refresh operations.

In addition to applicability in memory systems as described herein, techniques for retention aware refresh operations may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by reducing data loss in memory cells and enabling use of weaker retention memory cells, which may support scaling for greater processing power.

In addition to applicability in memory systems as described herein, techniques for retention aware refresh operations may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by reducing power draw of devices, as well as reducing material usage in manufacturing by reducing a die size in products. Further, the techniques described herein may enable use of a greater quantity of memory cells by allowing lower retention rates, which may increase manufacturing yield while reducing material waste caused by manufacturing redundant memory cells otherwise used to replace those with weaker retention characteristics.

Features of the disclosure are illustrated and described in the context of systems and architectures. Features of the disclosure are further illustrated and described in the context of retention distribution, retention distribution charts, flow diagrams, circuit diagrams, block diagrams, and flowcharts.

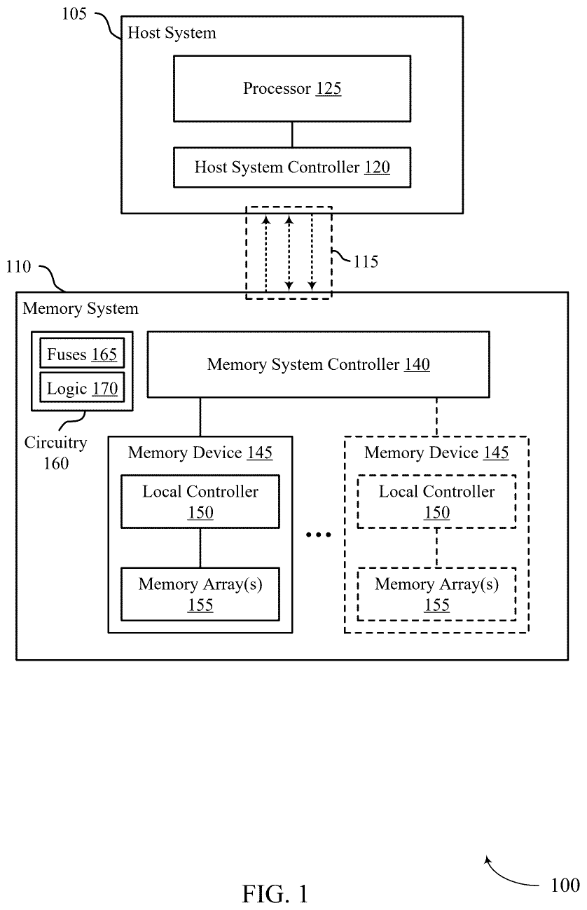

FIG. 1 illustrates an example of a system 100 that supports retention aware refresh operations in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some examples, the system 100 may support LORAR schemes and/or concurrent LORAR schemes to accommodate weaker retention cells. For example, the memory system 100 may identify CBR sets (e.g., via the memory system controller 140, one or more local controllers 150 or communication with a host system controller 120) that include memory cells with relatively weak retention characteristics (e.g., memory cells with relatively low retention rates involving more frequent refresh operations), and may program additional fuses with addresses corresponding to such sets (e.g., fuse CBR sets), where such sets may be referred to as fuse CBR sets. In some cases, a memory device 145 may characterize retention of one or more memory cells of the memory device, and may program fuses with addresses of sets of weaker memory cells. In some cases, such characterization and programming may be performed during manufacture or testing. Additionally, or alternatively, the memory system 100 may characterize memory cells of one or more memory devices 145, or one or more external devices or other controllers may characterize memory cells of memory devices 145. In some examples, weak retention rows may be identified during system operation (e.g., by inspecting if an error correction circuitry (ECC) engine detects one or more bit failures). Further, CBR sets may be added and/or removed throughout system operation, as determined by devices of the system 100.

In some cases, the memory system 110 may include circuitry 160 to support LORAR techniques, where the circuitry 160 may include one or more sets of fuses 165 corresponding to different fuse CBR sets including weaker retention memory cells. The circuitry 160 may also include logic 170 to support comparisons to thresholds, counters, multiplexors, among other components to support the techniques described herein. In some cases, the circuitry 160 may be included in the memory system 110, or in the memory system controller 140, and in some cases be shared by one or more memory devices 145. The memory system 110 may also include multiple instances of the circuitry 160 that may correspond to different memory devices 145 or to subsets of memory cells of the memory devices 145. Additionally, or alternatively, circuitry 160 may be added to each memory device 145, to each local controller 150, or to each memory array 155, or in a combination thereof. Further, multiple instances of the circuitry 160 may be added to each memory device 145 (or local controller 150 or memory array 155). Any placement or combination of circuitry 160 with relation to the memory system 110 may also be considered.

In some examples, one or more fuses of the fuses 165 may store an address of a respective fuse CBR set of memory cells (e.g., with one or more rows of memory cells with, for example, one or more fuses per row, or one or more fuses for a set of multiple rows) while the logic 170 may be coupled with one or more controllers and CBR sets (e.g., CBR sets, fuse CBR sets). While performing refresh operations for a total quantity of CBR sets (e.g., using a CBR counter), after every X CBR sets, a refresh operation may be performed for fuse CBR sets. In some cases, tracking such refresh operations and selecting addresses may be performed by channel logic of the logic 170, which may be shared between one or more devices and banks (e.g., associated with one or more channels 115). In some cases, a concurrent LORAR scheme may be implemented. For example, the logic 170 may represent channel logic and bank logic, where individual bank logic may be included for each bank of memory cells of the memory system 110. Utilizing separate bank logic may enable refreshing a quantity of respective fuse CBR sets during a refresh operation (e.g., a fuse CBR set refresh operation), enabling a greater quantity of overall fuse CBR sets to be refreshed (e.g., at a time).

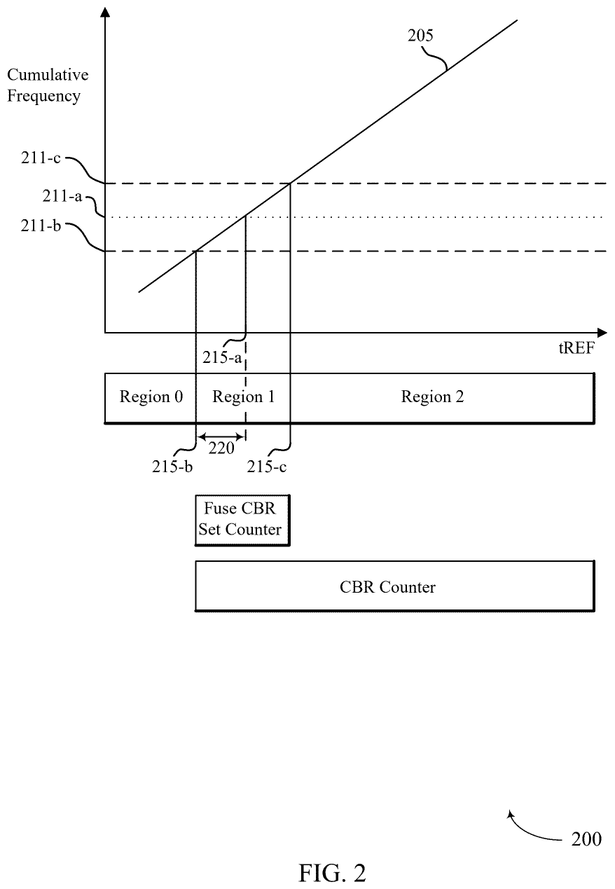

FIG. 2 shows an example of a retention distribution chart 200 that supports retention aware refresh operations in accordance with examples as disclosed herein. One or more aspects of the retention distribution chart 200 may be implemented by one or more aspects of the system 100. For example, the retention distribution chart 200 may illustrate a distribution representing relative quantities of memory cells of memory arrays 155 associated with different refresh requirement times tREF (e.g., associated with a retention time of the memory cell). For example, the x-axis may illustrate different tREF values (e.g., increasing from short tREF to longer tREF values in milliseconds, among other timing values), while the y-axis may illustrate an increasing cumulative frequency of memory cells (e.g., quantity of memory cells) associated with the tREF values (e.g., increasing from lower frequency to greater frequency of memory cells with a tREF value). The retention distribution chart 200 may in some examples represent a logarithmic scale charting of tREF and frequency values. In some cases, the retention distribution chart 200 may illustrate one or more processes supporting global LORAR schemes and concurrent LORAR schemes as described herein.

For example, a memory system 110 retention distribution chart 200 may support refresh operations, where refreshing one or more memory cells may be tracked by one or more counters. For example, a CBR counter may be incremented (e.g., through a row address space) for each refresh operation and refresh command, and may in some cases be associated with multiple rows for each counter value if row address compression is supported. For example, each CBR counter value (0, 1, 2, etc.) may be associated with one or multiple corresponding rows of memory cells that may be refreshed together, which row(s) may represent a CBR set. In some cases, a first CBR counter value (e.g., 0) may be associated with refreshing a first set of rows (e.g., a first row, multiple first rows) within each of multiple different sub-spaces of one or more array spaces (e.g., within a memory device, across multiple memory devices), while the next CBR counter value may be associated with refreshing a next set of rows (e.g., a second row, multiple second rows) within each of the multiple different sub-spaces. In some cases, the next set of rows may be physically adjacent to the first set of rows, or may be separated by one or more rows. A PRAC counter may also be supported, where a PRAC counter may track a quantity of memory cells of a row that are activated (e.g., may track using one or more bits in a row), and may indicate which rows are to be refreshed after a threshold PRAC count value. In some cases, if PRAC is supported, the next set of rows may be adjacent to the first set of rows.

In some examples, a time by which all cells in a memory system (e.g., DRAM system with one or more DRAM devices) are to be refreshed may be referred to as a tREF value. However, memory cells within a memory system (e.g., the memory system 110) may exhibit differences (e.g., slight differences) in characteristics due to manufacturing processes, and thus may be associated with different tREF values. As illustrated in FIG. 2, a distribution 205 may increase in frequency of memory cells as tREF increases, and in some cases may be linear (e.g., may have a linear relationship when both the x and y axes are on a log scale). Thus, when defining a tREF value for a total quantity of memory cells of a memory system, tREF may be set based on a memory cell with a lowest respective refresh time (e.g., a leakiest cell). For example, a tREF value 215-a may represent a repairable threshold tREF and may correspond to a quantity, or frequency, of memory cells 211-a, where any memory cells below the tREF value 215-a may be repaired (e.g., rows with such memory cells may be replaced with redundant rows of memory cells). However, as illustrated in FIG. 2, such memory cells may represent a relative minority of an overall distribution 205 as many memory cells may support much larger tREF values than what is selected to accommodate the minority. Thus, the overall memory system may be limited by a relatively small quantity of memory cells (e.g., a minority).

As memory cell density increases, retention time may decrease due to increased leakage and reduced cell capacitance (e.g., iOFF increases). In some cases, various circuit design options may be implemented to prevent failure due to retention. For example, to ensure retention in a threshold quantity of memory cells, some memory systems may increase an internal refresh rate to reduce an effective tREF (e.g., refresh rate may be inversely proportional to tREF). However, doing so may increase power consumption associated with refresh operations. tREFI may also be decreased to increase the refresh rate, but as tREFI may be predefined, this may result in using a smaller tREFI value than needed for one or more stronger retention memory cells. Other considerations may include adding additional error correction operations (e.g., double error correction) to mitigate failures in cells with weaker retention. Further, a sense margin may be increased by adjusting an array architecture to increase tREF (e.g., increasing sense margin by adopting a 2T2C configuration, a 2TIC configuration, or using a shorter bitline). However, either solution may increase a die size and result in less array efficiency ((area dedicated to array/total die area) * 100), while error correction may further increase timing to perform additional error correction check operations.

Other solutions may involve retention aware refresh schemes that may involve retention distributions, for example, by performing refresh by use of activate and precharge commands to strategically issue refresh (e.g., using activate and precharge commands instead of refresh commands). However, retention aware refresh schemes may increase a refresh overhead (e.g., for a controller or operating system) as activate and precharge commands may be issued for each row (instead of a refresh command for multiple rows), or by involving complex tables to store additional information. Further, some retention aware refresh schemes may involve providing a CBR counter value or other parameter (e.g., read CBR count, write CBR count, dummy refresh, skip refresh) to a controller, or may involve commands to read or write refresh addresses (e.g., CBR addresses). However, providing such information to a controller may give a controller insight into sensitive information concerning a memory device, which may reduce security. For example, providing a CBR counter to a controller may result in data loss due to one or more cells failing to receive a refresh, as well as in row hammer mitigation failure. Row hammer mitigation failure may in some examples be due to refresh not occurring appropriately due to a controller failing to maintain a CBR counter in a correct manner. In some cases, if a refresh does not occur appropriately, row hammer mitigation circuitry may fail to prevent data corruption of victim cells. Some schemes may involve users specifying regions where data retention may not be guaranteed, and refreshes to such regions may be blocked or redirected to areas where data retention is required. However, such blocking or redirection may result in data loss. Further, on-die retention aware refresh schemes may include added circuitry for refresh (e.g., hash circuits, comparison circuits), however this circuitry may increase complexity of a device. Further, such schemes may fail to conform to one or more defined refresh parameters. Thus, a solution may be desired to, without increasing power consumption, accommodate memory cells with relatively weaker retention while meeting one or more refresh parameters and having a relatively smaller die size impact.

As described herein, the retention distribution chart 200 may illustrate a method for implementing a LORAR scheme. For example, a LORAR scheme, such as a global LORAR scheme, may involve a memory system 110 adding additional fuses (e.g., in a memory system 110, in a memory system controller 140, in one or more memory devices 145, in one or more local controllers 150, and/or in one or more memory arrays 155) to accommodate a quantity of CBR sets, where such CBR sets may be referred to as fuse CBR sets, or memory element CBR sets (e.g., sets of non-volatile memory elements, volatile memory elements, or both). That is, as used herein, a “fuse” may refer to any type of non-volatile storage element. Additionally, or alternatively, a “latch” as described herein, may refer to any type of memory element (e.g., non-volatile memory elements, volatile memory elements), and a memory element (e.g., a second memory element, a plurality of second memory elements) may refer to a latch (or latches). Further, all instances of fuses, latches, fuse programmed CBR sets, counters, among other circuitry and components relating to fuses as described herein with respect to FIGS. 1-11, may additionally, or alternatively, apply generally with respect to any memory element, including any combination of non-volatile memory elements (e.g., fuses, antifuses, etc.) and/or volatile memory elements (e.g., latches, DRAM cells, SRAM cells, and the like). For example, an array may be characterized (e.g., during manufacturing) such that each CBR set is tested for an associated tREF, where a weakest cell in a CBR set may determine a corresponding tREF (e.g., a CBR set tREF). In some cases, a CBR set may be classified as “weak” if a corresponding CBR set tREF is below a weak threshold, and one or more fuses (or other types of memory elements) may be programed to define weak CBR sets, or fuse CBR sets (or other types of memory element CBR sets), once classified. For example, in FIG. 2, in place of using the single tREF value 215-a as a threshold, two threshold tREF values may be defined, including a shorter tREF value 215-b (with corresponding quantity or frequency 211-b) and a longer tREF value 215-c (with corresponding quantity or frequency 211-c).

Memory cells characterized with retention involving a tREF value below 215-b may be part of a region (e.g., region 0) that may be repaired, while memory cells with a tREF equal to or above the tREF value 215-b (e.g., weak threshold) but below the tREF value 215-c may be part of a different region (e.g., region 1) that is classified as “weak,” and may be associated with the shorter tREF value 215-b. Memory cells associated with a tREF greater than the tREF value 215-c (e.g., strong threshold) may be part of yet another region (e.g., region 2) of “strong” memory cells associated with a tREF equal to or above the tREF value 215-c. The memory system may involve a relatively small quantity of fuse programmed CBR sets (e.g., a minority), which may in some cases be referred to as fuse CBR sets (or other memory element CBR sets if other memory elements are involved).

To accommodate the defined fuse CBR sets and the shorter tREF value 215-b, a REF value 215-a (e.g., a single tREF value 215-a) may be adjusted to be the shorter tREF value 215-b for the fuse CBR sets. In some cases, adjusting the tREF value 215-a to accommodate the tREF value 215-b may result in extending the long tREF value (e.g., for normal refresh operations) from 215-a to 215-c for normal refresh operations. Thus, the memory system 110 may perform one or more additional refresh operations using the shorter tREF value 215-b in addition to performing regular refresh operations using the longer tREF value 215-c. For example, refresh commands (e.g., REF commands) may be issued by a memory controller (e.g., the memory system controller 140, local controllers 150) according to or otherwise at a periodic interval tREFI, where REF commands may use a refresh address supplied by either a global CBR counter, or a fuse CBR set counter, at a ratio of refresh commands. In some cases, the ratio may define a quantity of CBR counter refresh operations supporting the longer tREF value 215-c before performing an additional refresh operation for one or more fuse CBR sets supporting the shorter tREF value 215-b. In some examples, a cycle of a dedicated counter (e.g., a refresh command counter) may be implemented to track the ratio, or to otherwise define the ratio.

In some cases, at the shorter tREF value, 215-b, the memory device may cycle through the fuse programmed weak CBR sets (e.g., fuse CBR sets) and may perform a refresh operation for a fuse CBR set within a time defined by the shorter tREF value, which may be generally represented by Equation 1 below:

$$Short tREF = AddrRatio \times n \times tREFI \qquad ( 1 )$$

In Equation 1, n may represent a quantity of fuse programmed CBR sets, while AddrRatio may represent a ratio of a quantity of CBR Counter refresh operations before a fuse programmed CBR set refresh operation is performed plus one. In another example, at the longer tREF value 215-c, the memory device may cycle through the entire CBR counter. For example, the memory device may perform a refresh operation involving a next CBR set of the full set of CBR sets within a time defined by the longer tREF value 215-c, which may be generally represented by Equation 2 below:

$$Long tREF = \frac{AddrRatio}{AddrRatio - 1} ( \# CBR Counter States ) tREFI \qquad ( 2 )$$

In some embodiments, functions involving processes similar to hard Post Package Repair (hPPR) and soft Post Package Repair (sPPR), among other functions, may be implemented to add or remove fuse CBR sets. In some cases, CBR sets may be added or removed based on errors observed in the memory system 110. For example, a fuse CBR set may be added if accessed data is associated with an error. Additionally, or alternatively, a CBR set may be removed if a memory location is no longer associated with an error. In some cases, such functions may be triggered by one or more external commands (e.g., by commands issued by the memory system controller 140 to one or more memory devices 145) or by internal operations (e.g., by operations within a memory device 145). In some examples, an hPPR-like function may result in a change (e.g., a permanent change) that would persist across power cycles due to the programming of one or multiple non-volatile memory elements (e.g., fuses, antifuses, etc.). Additionally, or alternatively, an sPPR-like function may result in a change (e.g., a temporary change) that may persist throughout a power cycle due to the programming of one or multiple volatile memory elements (e.g., latch, DRAM cell, SRAM, and the like).

In some cases, a repairable threshold may be improved (e.g., may allow more memory cells to be accepted based on a lower threshold) by allowing weaker cells to be refreshed using another tREF value. For example, the weak cells of the fuse CBR sets may be refreshed during both refresh operations initiated for the fuse-programmed CBR set counter and refresh operations initiated for the CBR counter, as the CBR counter may increment through each of the CBR sets including the fuse CBR sets. Stronger cells of other CBR sets of region 2 may be refreshed during operations initiated by the CBR counter, as such memory cells may allow a longer time between refreshes. Thus, by implementing a short tREF for a subset of memory cells in region 1 and a longer tREF for memory cells in region 2 and region 1, the memory system 110 may accommodate a greater quantity of memory cells with a shorter tREF value 215-b (e.g., within a range 220) that would otherwise be repaired if using an overall longer tREF value 215-a for all memory cells. Thus, a yield may be increased by allowing additional weaker cells to be refreshed within one or more defined parameters, as a lower short tREF may allow weaker cell process characteristics to become acceptable.

Further, LORAR may thus also accommodate weak retention memory cells without decreasing tREFI, and using a relatively short tREF and a relatively long tREF may support higher scaling and higher memory cell density by enabling memory cells that are smaller with more leakage and less retention to be accepted. Further, reduced refresh power may be supported by ignoring one or more row activations during refresh that may be omitted, while incurring a reduced refresh overhead by allowing a higher tREFI. Further, sharing of sensitive information may be avoided (e.g., may not be required) while providing compatibility with one or more existing devices or parameters, including PRAC row hammer mitigation. Data loss may also be prevented in comparison to other retention aware refresh schemes.

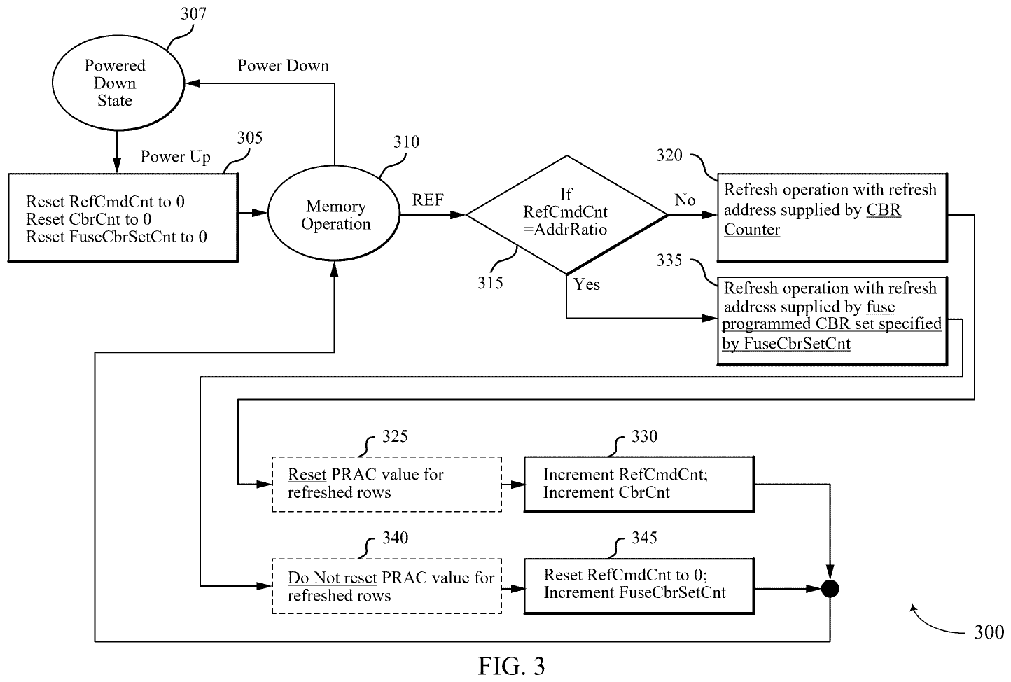

FIG. 3 shows an example of a flow diagram 300 that supports retention aware refresh operations in accordance with examples as disclosed herein. One or more aspects of the flow diagram 300 may be implemented by one or more aspects of the system 100 and the retention distribution chart 200. For example, the flow diagram 300 may illustrate a procedure for performing one or more refresh operations in the memory system 110 according to the shorter tREF value 215-b and the longer tREF value 215-c. In some cases, the memory system 110 may support at least three counters, including a CBR counter to generate a value or signal CbrCnt, a fuse CBR set counter to generate a value or signal FuseCbrSetCnt (e.g., <┌log₂(n)−1┐, 0>), and a refresh command counter to generate a value or signal RefCmdCnt. In the following description of the flow diagram 300, the operations may be performed (e.g., reported or provided) in a different order than the order shown, and some operations also may be omitted from the flow diagram 300, or other operations may be added to the flow diagram 300. Further, although some operations or signaling may be shown to occur at different times for discussion purposes, these operations may actually occur at the same time or at least partially concurrently.

At 305, the memory system 110 may power on. At power on, the memory system 110 may reset all of its counters (e.g., reset to a value of 0). At 310, the memory system 110 may perform one or more memory operations or other operations, including accessing one or more memory cells. The memory system 110 may, in some cases, enter a power down state at 307, and later power on (e.g., for a subsequent time) at 305.

For a quantity of refresh operations, the memory system 110 may proceed to 315, where the memory system may compare a value of RefCmdCnt to a threshold value, such as a ratio AddrRatio, to determine whether to perform a refresh operation based on CbrCnt or based on FuseCbrSetCnt. In some cases, AddrRatio may be a value generated by a test mode fuse option (e.g., an option configured and selected for supporting added refresh operations for fuse CBR sets).

If RefCmdCnt does not equal AddrRatio (e.g., if a threshold value is not satisfied), the memory system 110 may perform refresh operations for a next CBR set defined by the CBR counter. For example, the memory system 110 may select an address provided by CbrCnt and may proceed to 320 to perform a refresh operation on one or more rows corresponding to a refresh address sourced from a value of the CBR counter. In some cases, comparison circuitry may output an address select value AddrSel so that AddrSel is equal to 0 (e.g., the signal is low) based on the comparison. After performing the refresh operation, the memory system 110 may proceed to increment one or more counters. In some cases, if PRAC is supported, the memory system 110 may proceed to 325 to reset a PRAC value for refreshed rows (e.g., rows of a CBR set corresponding to the CBR counter value). The memory system 110 may proceed to 330 and may increment RefCmdCnt and CbrCnt.

If RefCmdCnt is equal to AddrRatio, the memory system 110 may proceed to 335 to perform a refresh operation on one or more rows corresponding to a refresh address sourced from a fuse programmed CBR set. For example, the memory system 110 may select an address provided by a FuseCbrSet multiplexor, and may refresh a next fuse CBR set using an additional refresh operation defined by the ratio AddrRatio, where the next fuse CBR set for refresh may be specified by a current value of the fuse CBR set counter FuseCbrSetCnt.

In some cases, comparison circuitry may output an address select value AddrSel so that AddrSel is equal to 1 (e.g., the signal is high) based on the comparison. In some cases, if PRAC is supported, the memory system 110 may proceed to 340, and may refrain from resetting a PRAC value for any refreshed rows (as PRAC may be reset for CBR counter refresh operations but not for fuse CBR set refresh operations). The memory system 110 may proceed to 345 and may reset RefCmdCnt and increment FuseCbrSetCnt. In some examples, refresh operations for fuse CBR sets may be configured to be performed between section boundaries of the CBR counter when selecting a fuse CBR set address.

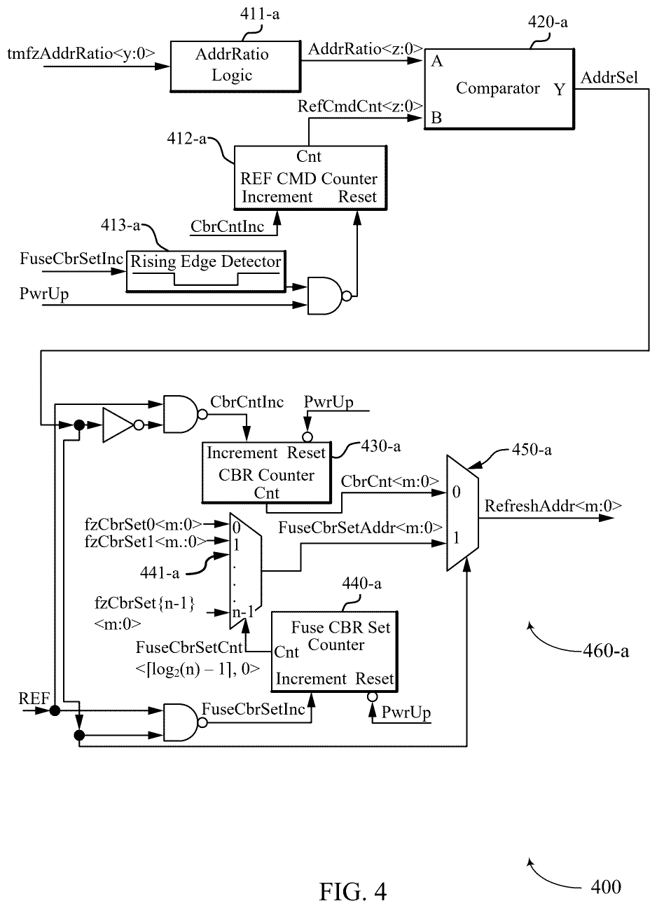

In some cases, the methods described herein may be performed for a global LORAR scheme as discussed with reference to FIG. 4. Further, the methods described herein may be performed for a concurrent LORAR scheme. For example, one or more refresh operations may be performed for multiple banks concurrently.

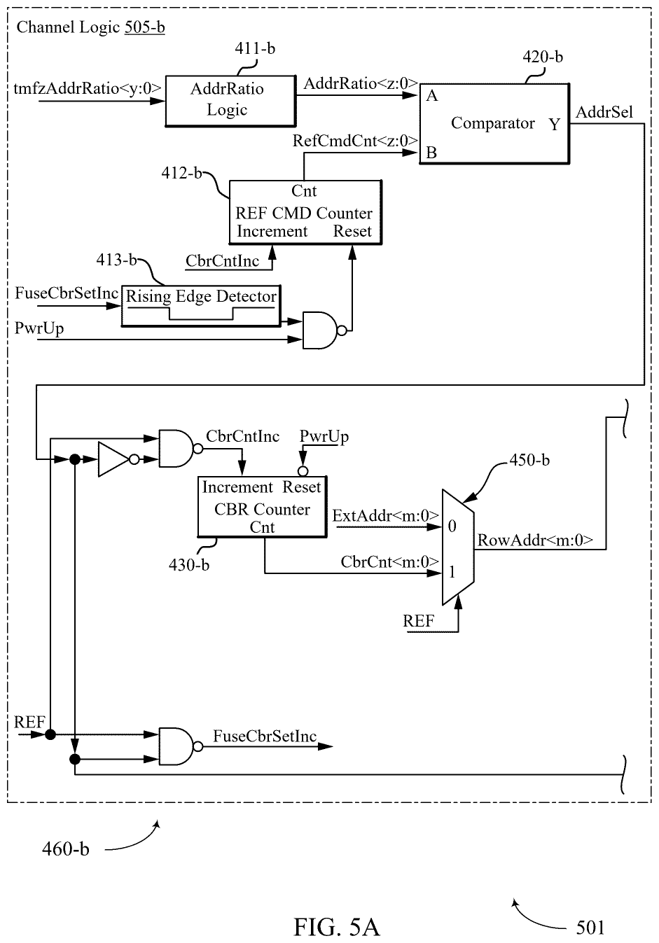

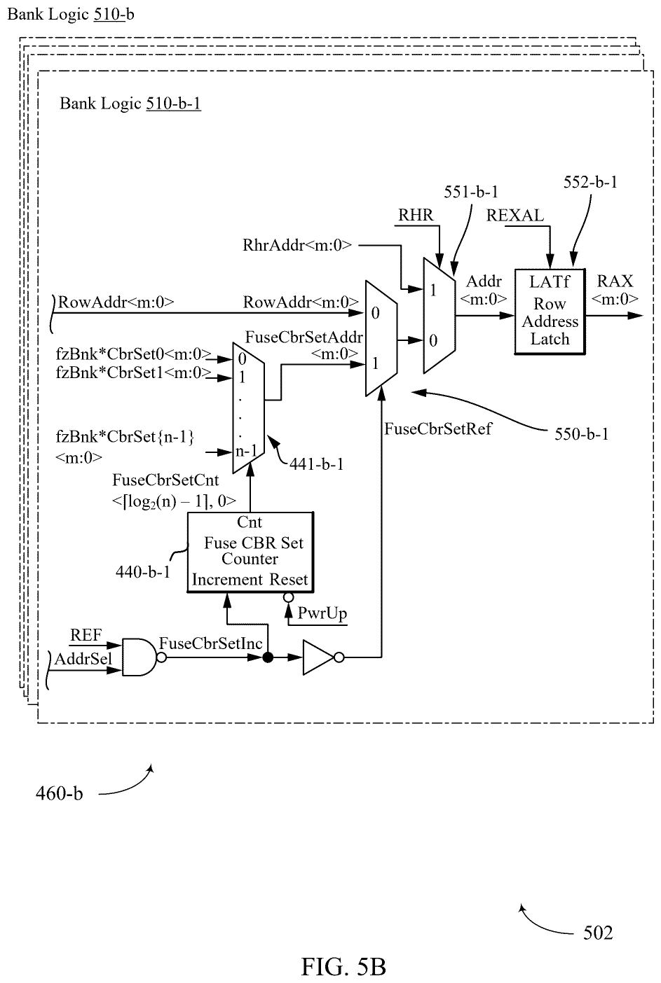

FIG. 4 shows an example of a circuit diagram 400 that supports retention aware refresh operations in accordance with examples as disclosed herein. One or more aspects of the circuit diagram 400 may be implemented by one or more aspects of the system 100, the retention distribution chart 200, and the flow diagram 300. For example, the circuit diagram 400 may illustrate various circuitry and components of circuitry 460, such as circuitry 460-a, for supporting selection of a next CBR set or a next fuse CBR set for a refresh operation using a ratio AddrRatio as discussed herein, where the circuitry 460-a may be an example of the circuitry 160 (e.g., including logic 170, fuses 165, or both in the memory device 145, local controller 150, or other locations) as described with respect to FIGS. 1-3. In some cases, the circuitry 460-a may illustrate one or more additional components which may be part of (e.g., in a same location within the memory system 110 as), or separate from, the circuitry 160. Further, while FIG. 4, as well as FIG. 5A-8 may illustrate different examples of circuitry, FIGS. 4-8 may not be limited to such examples, and may be implemented using different variations of circuit components to achieve LORAR and concurrent LORAR methods. In some cases, FIG. 4 may illustrate circuitry supporting a global LORAR scheme as described herein.

The circuitry 460-a may include circuitry for determining whether a quantity of CBR refresh operations have been performed to determine if a fuse CBR set refresh operation may be performed. For example, the circuitry 460-a may include comparison circuitry, such as a comparator 420-a (e.g., a digital comparator) with inputs A and B and output Y. The output Y may output an AddrSel signal, which may be high (e.g., Y=1) if inputs A and B are equal (e.g., A=B), and otherwise may be low (e.g., Y=0). The output Y may be coupled with a CBR counter 430-a and a fuse CBR set counter 440-a, while the input A may be coupled with ratio Logic 411-a to receive a ratio value AddrRatio (e.g., AddrRatio <z:0>, where <z:0> may represent a quantity of bits up to a bit z) and the input B may be coupled with a refresh command counter 412-a to receive a refresh command count value RefCmdCnt (e.g., RefCmdCnt<z:0>). In some cases, RefCmdCnt may be compared to AddrRatio so that an output of the comparator 420-a may generate the signal AddrSel, which may determine a source of a refresh operation. In some examples, an AddrSel value of 0 may indicate that a refresh operation is to use a refresh address supplied by a CBR counter 430-a (e.g., a next CBR set) while an AddrSel value of 1 may indicate that a refresh operation is to use a refresh address supplied by a fuse CBR set specified by the fuse CBR set counter 440-a.

In some cases, the AddrRatio may represent a ratio of selecting a refresh address from the CBR counter to selecting a fuse programmed CBR set, and may be specified by a test mode fuse (e.g., tmfzAddrRatio) to generate an AddrRatio value. The refresh command counter 412-a may increment (e.g., count) through a quantity of refresh operations until a fuse CBR set refresh operation is to be performed based on the ratio AddrRatio. For example, the refresh command counter 412-a may increment (e.g., count) up to AddrRatio, after which the counter may be reset to 0 so as to perform refresh operations for CBR sets again. In some cases, the refresh command counter 412-a may count based on an increment input with a CBR counter increment signal, CbrOntInc, and a second Reset input for resetting, which may be driven by a NAND operation of a fuse CBR set increment signal FuseCbrSetInc input into a rising edge detector 413-a and a power up signal. In some cases, the power up signal may be low during a portion of a power up routing (e.g., at 305 with respect to FIG. 3) and may be high during a memory operation.

In some examples, the fuse CBR set counter 440-a and the refresh command counter 412-a may be replaced by one or more logic components (e.g., digital logic components, not shown). In such examples, the logic components may be configured to functionally derive the values otherwise associated with the fuse CBR set counter 440-a and the refresh command counter 412-a.

In some examples, the CBR counter 430-a may include an increment input to receive a CBR counter increment CbrOntInc which may be determined based on a value of AddrSel (e.g., via a NAND gate and an inverter as illustrated). For example, the increment input may be positive edge triggered, and for a refresh operation, CbrOntInc may have a value of 1 (e.g., may pulse high) to indicate to increment the CBR counter 430-a (e.g., rising edge of CbrCntInc increments the CBR counter) when AddrSel is 0 (e.g., e.g., when doing a normal refresh operation). Such incrementing may occur after, before, or during performance of a refresh based on a CBR counter. CbrOntInc may further have a value of 0 (e.g., signal may pulse low) to indicate to refrain from incrementing when AddrSel is 1 (e.g., when doing refresh for a fuse CBR set). The CBR counter 430-a may also include a reset input, which may include an inverted PwrUp signal (e.g., reset input may be positive level triggered so that, for example, an inverter may allow a negative level trigger to reset, where CBR counter 430-a may be reset at power up, as PwrUp may be low at power up). The CBR Count may include an output Cnt to output an address value CbrCnt (e.g., CbrCnt<m:0>) corresponding to an address of a current CBR set based on a value of the counter.

In some examples, the fuse CBR set counter 440-a may also include an increment input to receive a fuse CBR set increment value FuseCbrSetInc which may also be determined based on a value of AddrSel (e.g., via a NAND gate as illustrated) as well as a reset input to receive an inverted PwrUp signal. For a refresh operation, FuseCbrSetInc may instead have a value of 0 (e.g., may pulse low) to refrain from incrementing when AddrSel is 0, or a value of 1 (e.g., may pulse high) to indicate to increment when AddrSel is 1 (e.g., after a fuse CBR set refresh, while other examples may support incrementing before or during performing of a fuse CBR set refresh). The fuse CBR set counter 440-a may include an output Cnt, which may be coupled with a fuse CBR set multiplexor 441-a (e.g., FuseCbrSet multiplexor), and may count up to n−1(corresponding to a total quantity of fuse CBR sets n before cycling to 0). In some cases, the fuse CBR set multiplexor 441-a may select and output a next fuse CBR address FuseCbrSetAddr (e.g., FuseCbrSetAddr<m:0>) based on a value of the fuse CBR set counter 440-a, including addresses fzCbrSet0, fzCbrSet1, up to fzCbrSet {n−1}, each with m bits, for fuse CBR sets 0, 1, through n−1. Each fuse CBR set may include an address that may be associated with one or more rows of memory cells. In some cases, for a global LORAR system, a fuse CBR set address may be sent to each bank of one or more memory devices (e.g., to each bank of a die or of multiple dies) to refresh corresponding rows across the banks of the system. Additionally, or alternatively, the methods and functions described herein with reference to the fuse CBR set multiplexor 441-a and the fuse CBR set counter 440-a could by using one or more other components or circuitry in combination with, or alternative to, the multiplexor, the counter, or both (e.g., such functions could be implemented without a multiplexor and/or counter).

The circuitry 460-a may also include an address multiplexor 450-a configured to select the address CbrCnt or the address FuseCbrSetAddr based on a value of AddrSel. For example, the address multiplexor 450-a may include an input associated with a 0 value and coupled with the CBR counter 430-a to receive CbrCnt, and an input associated with a 1 value and coupled with the fuse CBR set multiplexor 441-a to receive FuseCbrSetAddr. The address multiplexor 450-a may also include a selection input to receive AddrSel, and an output for outputting a selected address RefreshAddr (e.g., RefreshAddr<m:0>), which may be routed to each bank of one or more memory devices via a global address bus.

In an example of an operation, at a relatively small tREF, a memory system (e.g., including one or more memory devices) may cycle through fuse programmed weak CBR sets by iterating through the fuse CBR sets, where each fuse CBR set may be an input to a FuseCbrSet multiplexor 441-a as discussed herein. The fuse CBR set counter 440-a may be incremented after each refresh operation (e.g., after each REF command) for which a refresh address corresponds to a fuse CBR set, and the fuse CBR set counter 440-a may select which fuse CBR set to pass to the output of the fuse CBR set multiplexor 441-a based on a fuse CBR set counter value. In some examples, at a relatively larger tREF value, a memory system including the circuitry 460-a may cycle through the CBR counter 430-a. For example, the CBR counter 430-a may be incremented for each refresh cycle for which an refresh address is a CBR counter value. In some cases, a tmfzAddrRatio value may disable LORAR. In such an example, a value of AddrSel may be 0 (e.g., low) regardless of inputs to the comparator 420-a. Further, another value of tmfzAddrRatio (e.g., a second option) may result in an AddrSel having a value of 1 (e.g., high) regardless of the inputs to the comparator 420-a, which may result in cycling through the fuse CBR sets (e.g., through only the fuse CBR sets).

In some examples, PRAC may be supported by the circuitry 460-a. For example, to generate the refresh address RefreshAddr based on the CBR counter 430-a, the CBR counter 430-a may be incremented for one or more memory arrays, in which case a refresh command (e.g., REF command) may reset a PRAC value for one or more rows associated with a current CBR set. In some cases, resetting a PRAC value may be based on adjacent rows being refreshed at a time relatively soon after a refresh operation (e.g., associated with a subsequent refresh command). In some cases, the CBR counter cycle time may increase by an amount of time which may result in a reduction of a PRAC mitigation value.

In another example, to generate the refresh address RefreshAddr based on a fuse CBR set, the fuse CBR set counter 440-a may not increment linearly based on iterating through the fuse programmed CBR sets. For example, the fuse CBR set may be different than a next CBR set tracked by the fuse CBR counter, and so a refresh for an adjacent row to the fuse CBR set may occur at a later time (e.g., if the CBR counter is at a lower value). Therefore, a refresh command with a refresh address that is derived from a fuse programmed CBR set may refrain from resetting a refreshed PRAC value. In some cases, if refreshing between CBR counter refreshes becomes prohibited by PRAC, the fuse CBR set counter 440-a may be issued in between the section boundaries of CBR counter refresh operations.

In some examples, one or more commands, such as issued PPRs, may not affect operations performed by a memory system including the circuitry 460-a as PPR match may be disabled during refresh. In some examples, one or more refresh operations may be performed using a primary non-redundant array, and refresh of a redundant array may follow. Further, multiple groups of fuse-programmed CBR sets may be present. In some examples, each group may represent a respective tREF range. Additionally, or alternatively, each group may include a respective fuse CBR set counter 440 (e.g., a CBR set counter 440-a) and multiplexor 441 (e.g., a multiplexor 441-a).

In some examples, to further reduce a quantity of fuses used, a quantity of bits represented by each fuse programmed CBR set may be compressed or reduced. For example, splitting the array into multiple groups of CBR sets may enable fuse CBR bits to be hard tied vs. fuse programming, and may result in utilizing less fuses to represent fuse CBR sets. Further, additional refresh cycles and logic may be implemented to refresh one or more uncompressed values. In some examples, the circuitry illustrated in FIG. 4 may allow for a ratio or quantity of refresh cycles to be skipped. For example, refresh skipping may enable a reduction in refresh related power by skipping refreshes to reduce overall power, or removing skipping functionality and reducing refresh parallelism may reduce power consumption and peak power consumption. Further, skipping circuitry may be removed and a time between refresh commands may be increased, decreasing overhead. There may also be cases in which the memory system may overprovision a quantity of CBR sets (e.g., a quantity of fuse CBR sets to use), in which case another test mode fuse option (e.g., configuration option) may be included to allow the fuse CBR set counter 440-a to cycle at a lower value, or a relatively lower quantity of fuse CBR sets.

In some cases, by implementing the circuitry illustrated in FIG. 4, a die size, cost, and power consumption may be reduced, while accommodating weak retention memory cells. For example, the circuitry illustrated in FIG. 4. may be associated with relatively less die area and less power usage and overhead compared to implementing hash circuits, hash comparison circuits, or comparison circuits with fuse-programmed refresh addresses, as well as compared to using error correction code circuitry or other array architecture changes.

FIGS. 5A and 5B show examples of a circuit diagram 501 and a circuit diagram 502 that support retention aware refresh operations in accordance with examples as disclosed herein. One or more aspects of the circuit diagrams 501 and 502 may be implemented by one or more aspects of the system 100, the retention distribution chart 200, the flow diagram 300, and the circuit diagram 400. For example, the circuit diagrams 501 and 502 may illustrate channel logic 505-b and different bank logic 510-b of circuitry 460-b, for supporting selection of a next CBR set or a next fuse CBR set for a refresh operation using a ratio AddrRatio as discussed herein. The circuitry 460-b may be an example of circuitry 160 (e.g., in a memory system 110, in a memory system controller 140, in one or more memory devices 145, in one or more local controller 150, or in one or more memory arrays 155, or in a combination thereof). In some cases, FIGS. 5A and 5B may illustrate a first example of circuitry supporting a concurrent LORAR scheme as described herein.

In some examples, a refresh address in global LORAR may be sent to all banks of a memory system, however, each fuse CBR set refresh cycle may in some cases refresh a subset of weak rows of one or more CBR sets rather than a full set of weak rows. For example, a fuse CBR set may be grouped under Region 1 with a shorter tREF based on a weakest row (or memory cell) of the fuse CBR set, even if the fuse CBR set includes a relatively small quantity (e.g., one row) of rows that are classified as weak, which may be due to CBR counter compression and random distribution of defects. Thus, a refresh for such a fuse CBR set may refresh a relatively small subset of weak rows, rather than a full or larger set of weak rows (e.g., may refresh 1 or 2 weak rows within a large set of including mostly stronger rows).

In some cases, a greater quantity of fuse CBR sets n may be implemented to refresh additional weak rows but may result in an increase in a short tREF or a decrease in AddrRatio. To maintain a relatively short tREF value, AddrRatio may be decreased, but may result in an increased long tREF value and thus a quantity of weak rows to be covered may also increase. Further, if a short tREF value increases, additional weak rows may be unable to be refreshed and may be repaired. In some retention distribution cases, due to a higher short tREF value and/or higher long tREF value, not all cells may be refreshed according to one or more parameters. Further, to accommodate a greater quantity of fuses used for global LORAR, a layout may distribute fuse latches (or other memory elements) across one or more dies. However, such distribution may introduce additional routing from the fuse latches to the global LORAR circuit logic.

In some examples, concurrent LORAR may present a solution that may increase a quantity of weak rows refreshed per fuse CBR set refresh cycle. Further, concurrent LORAR may be compatible with a wider range of retention distributions than global LORAR, and may present a relatively efficient layout and routing for circuitry while avoiding increases in a die area. For example, a concurrent LORAR scheme may increase a quantity of weak rows that are refreshed during a short tREF time duration by adding fuse latches (or other memory elements) and a fuse CBR set multiplexor 441 to each individual bank of a memory system (e.g., a total quantity of FuseCbrSet multiplexors may be equivalent to a total quantity of banks of a memory system, such as the memory system 110). A fuse CBR set counter may also be added to each bank in some cases. In some examples, retention may be characterized (e.g., in factory, during manufacturing) across one or more dies so that rows are classified as weak when a tREF falls between a Short and Long tREF as described herein, where rows falling below short tREF may be repaired as discussed with respect to FIG. 2. In concurrent LORAR, CBR sets including identified weak rows may be fuse programmed on a per-bank basis.

In the example of FIG. 5A, channel logic 505-b may be illustrated, which may refer to logic shared across each bank of the memory system including the circuitry 460-b. Similar to FIG. 4, the channel logic may include AddrRatio logic 411-b, a refresh command counter 412-b, a rising edge detector 413-b to feed an input to a comparator 420-b, which may output AddrSel to a global CBR counter 430-b in the channel logic 505-b. The CBR counter 430-b may also cycle each long tREF and iterate through an entire array to refresh each row. As refresh commands are issued by a memory controller, at a ratio specified by AddrRatio, a refresh cycle based on a CBR counter (e.g., a normal refresh cycle) or a fuse CBR set refresh cycle may occur internally. For example, during a refresh cycle based on the CBR counter 430-b, a global refresh address for the banks derived by the global CBR counter 430-b may be used.

Further, an AddrSel value may be generated globally and routed to the banks. In another embodiment, FuseCbrSetInc could be generated globally and routed to the banks in addition to, or instead of, AddrSel. An address multiplexor 450-b (e.g., a channel address multiplexor) may be included to select between an output of the CBR counter 430-b and an external address, ExtAddr (e.g., ExtAddr<m:0>), which may be an address to be activated as specified by an activate (ACT) command. The output of the address multiplexor 450-b may be RowAddr<m:0>, which may be sent globally to each of the banks.

During a fuse CBR set refresh cycle, a bank specific refresh address may be used for each individual bank derived by a bank specific fuse CBR set multiplexor 441-b, which may select a respective fuse CBR set of that bank. For example, in the example of FIG. 5B, the circuitry 460-b may include different instances of bank logic 510-b, including a bank logic 510-b-1 as illustrated, which may include bank specific fuse CBR set circuitry. For example, the bank logic 510-b-1 may include a fuse CBR set counter 440-b-1 coupled with an increment and reset input with a Cnt output to a fuse CBR set multiplexor 441-b-1, which may be used to select an address of a fuse CBR set of that bank (e.g., fzBnk*CbrSet0<m:0>,fzBnk*CbrSet1<m:0>, up to fzBnk*CbrSet{n−1}<m:0>) based on the counter value. Thus, an instance of a fuse CBR set counter 440-b may in be included in each bank. In some cases, each fuse CBR set counter 440-b may have an identical value and may be incremented or reset together, and may iterate through the fuse CBR sets for each bank, and cycle each short tREF. Additionally, or alternatively, such methods or functions may be performed using other circuitry in combination with, or alternative to, different multiplexors and/or counters described herein.

In some cases, AddrSel may be used to select between the global row address bus RowAddr (e.g., common to all banks) and the output of a bank specific fuse CBR set multiplexor 441-b. In some examples, AddrSel may be low for a normal refresh cycle and high for a fuse CBR set refresh cycle, and may be a select input for a bank address multiplexor 550-b-1. When AddrSel is low, the bank address multiplexors 550-b across banks may each select the global address bus, but when AddrSel is high, the bank address multiplexors 550-b may select respective outputs of the fuse CBR set multiplexors 441-b in each bank. In some examples, for a fuse CBR set refresh cycle, multiple fuse CBR set addresses may be refreshed concurrently by targeting a weak row or rows in each bank of a die. The bank address multiplexors 550-b may also receive a FuseCbrSetInc signal (e.g., an inverted signal), which may be based on a refresh command and AddrSel.

Selection may thus be bank specific. For example, the bank address multiplexor 550-b-1 may be coupled with an input to a multiplexor 551-b-1, which may include a row hammer refresh (RHR) address (e.g., RhrAddr address which may be an output of RHR circuitry that may be a value of an identified victim row that requires a refresh to mitigate row hammer), and an RHR signal as inputs, and may output an Addr signal (e.g., Addr<m:0>). In some examples, Addr may be input into a row address latch 552-b-1 that may also include an input Row External Address Latch (REXAL) and output RAX (e.g., RAX <m:0>). Additionally, or alternatively, another memory element may perform one or more functions of the row address latch 552-b-1. In some cases, REXAL may represent an activation signal. REXAL may pulse high at a beginning of a row activation cycle to store (e.g., latch) a row address that is to be activated (e.g., a row address that is to be activated from the global row address bus), while RHR may be high during a row hammer refresh operation that may be triggered during a refresh command, allowing each bank to refresh a desired RHR related address.

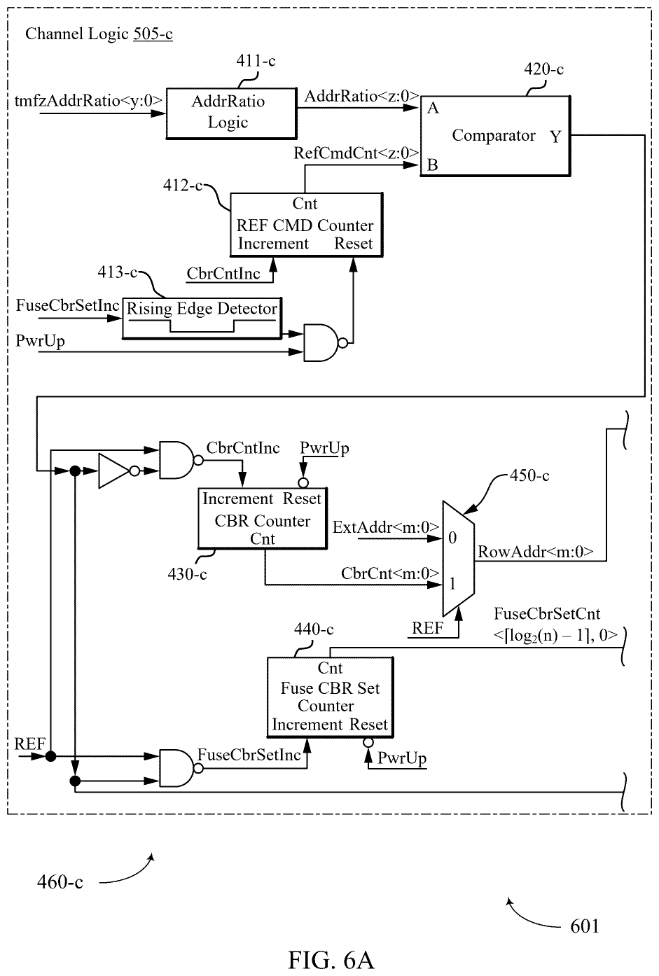

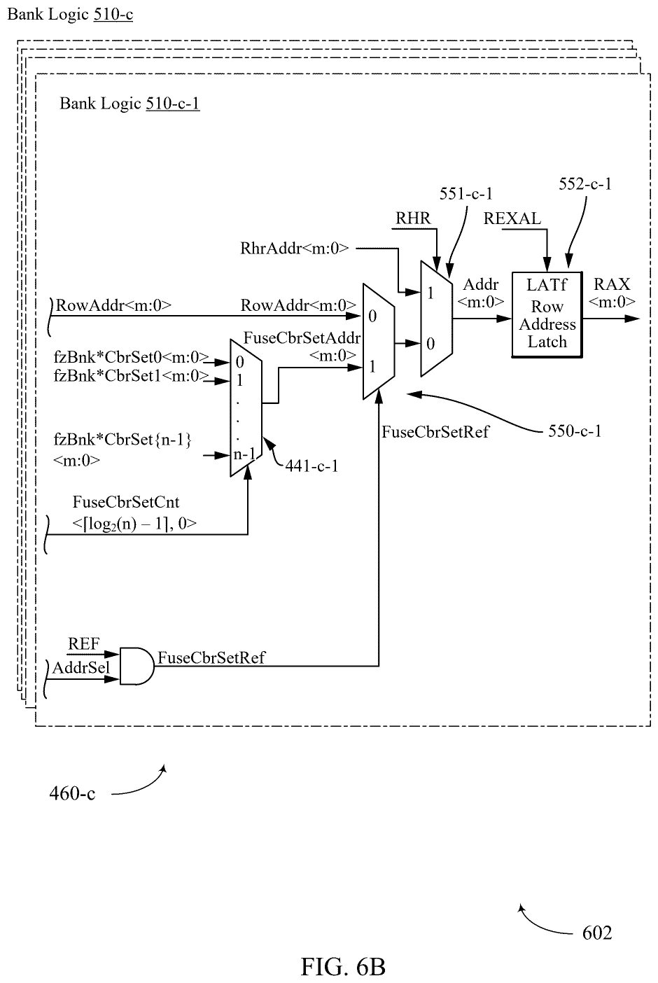

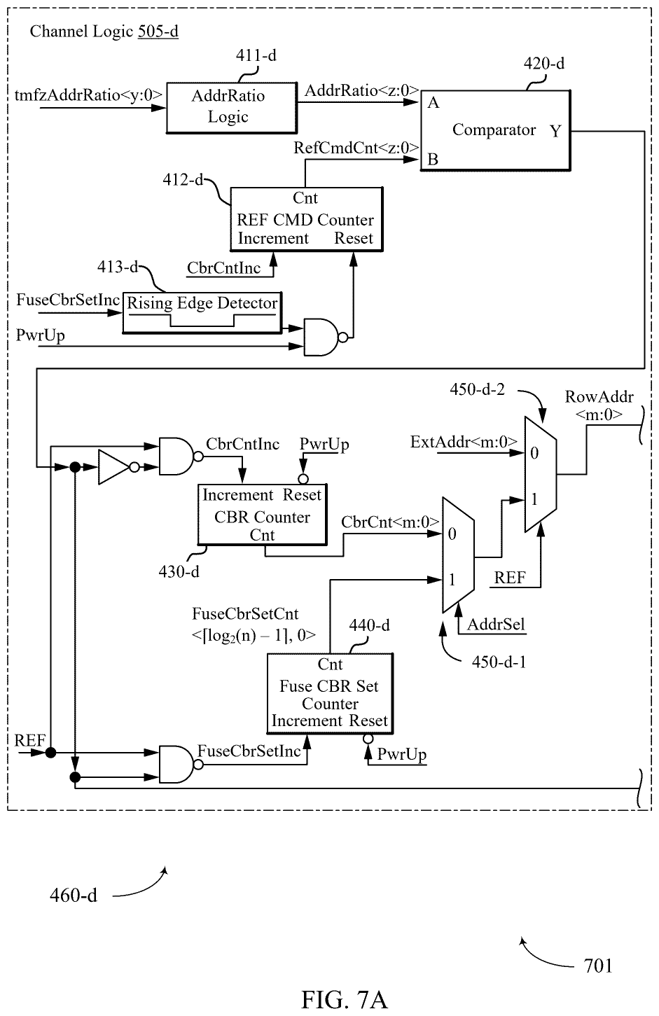

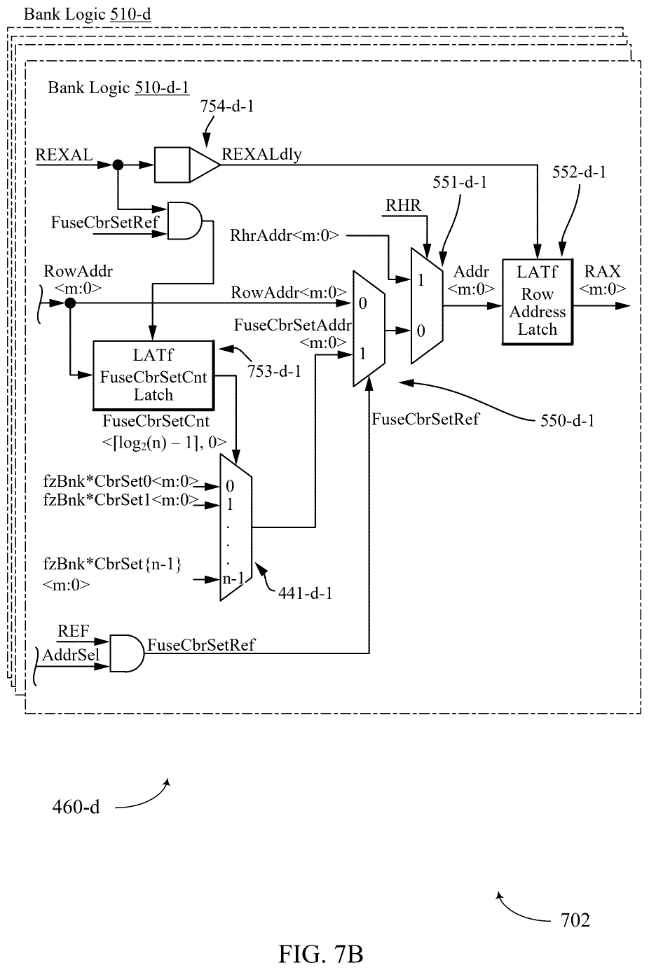

A concurrent LORAR operation may be similar to global LORAR, but may involve bank logic 510. For example, the general procedure of FIG. 3 may be followed, including similar counter actions, resets, and increments in accordance with different selected addresses, but with respect to the bank-specific circuit shown in FIGS. 5A and 5B, or according to additional examples as illustrated in FIGS. 6A-7B. For example, at powerup, a memory system may reset each counter throughout the channel logic 505-b and the bank logic 510-b. AddrRatio may be a value that is generated by a test mode or test mode fuse option, and when a refresh occurs, a normal refresh (e.g., RefCmdCnt does not equal AddrRatio) may source a refresh address from a value of the CBR counter 430-b where refresh is shared across all banks, and reset a PRAC value for refreshed rows while incrementing the refresh command counter 412-b and the CBR counter 430-b in the channel logic 505-b. For fuse CBR refresh operations (e.g., RefCmdCnt is equal to AddrRatio), a refresh address may instead be sourced from a bank-specific fuse CBR set on a per-bank basis (e.g., specific fuse CBR sets across the die as specified by the fuse CBR set counters 440-b).

Similar to global LORAR, if PRAC is supported, PRAC values may not be reset, while the refresh command counter 412-b may be reset in the channel logic 505-b and each individual fuse CBR set counter 440-b placement may be incremented for each of the bank logics 510-b (e.g., for fuse CBR set refresh operations). In some cases, the fuse CBR set counters 440-b may be allowed to fall out of sync. Further, the refresh command counter 412-b may cycle every AddrRatio and enable refresh addresses to be derived from CBR counters 430 or outputs of FuseCbrSet multiplexors 441.

Two distinct tREF intervals described herein, including a short tREF and long tREF, may be used together to refresh memory cells of the banks. For example, at a short tREF, a memory system may refresh through fuse programed CBR sets specifically targeting weak rows, where a short tREF for a concurrent LORAR scheme may be represented by Equations 3 and 4 below:

$$Short tREF = AddrRatio \times {n}_{per bank fuse sets} \times tREFI \qquad ( 3 )$$

$${n}_{per bank fuse sets} = \frac{{n}_{global}}{number of banks} \qquad ( 4 )$$

In some examples, n global from Equation 4 may be a quantity of fuse CBR sets across a die (or multiple dies) while n per bank fuse sets of Equations 3 and 4 may represent a quantity of fuse CBR sets specific to each bank. At a long tREF, the memory system may refresh through an entire CBR counter, and may be defined by Equation 2.

In some examples, similar to global LORAR, concurrent LORAR may be unaffected by PPR disabled during refresh, and fuses may similarly be reduced to compress or reduce a quantity of bits represented by each fuse programmed CBR set, and may involve some increased complexity with logic distributed across channels logic and bank logic. Concurrent LORAR may also result in additional potential refresh power savings as concurrent LORAR may refresh weak rows more efficiently and so may outpace the retention deficiencies of memory cells to allow internal tREF to be greater than external tREF. Further, greater internal tREF may be achieved by skipping refresh commands at a ratio, firing less rows per refresh command (e.g., may result in better distribution of power savings across time). There may also be cases where the memory system overprovisions fuse CBR sets (e.g., including another test mode or test mode fuse option allowing FuseCbrSet counter to cycle at a lower value, where the test mode fuse option may be stored, or latched).

Further, additional logic may be added in the bank logic 510-b to provide overprovisioning and test mode fuse options. Further, with increased complexity, there may exist multiple tREF groups of fuse-programmed CBR sets (e.g., each group may represent a tREF range), and on a per-bank basis, each tREF group may possess a respective fuse CBR set counter and multiplexor. Each set of each groups may also include a respective set of fuses (or a set of fuses per group). In some examples, additional logic may be distributed across channel and bank logic. In some examples, instead of distributing a fuse CBR set multiplexor for each bank, a fuse CBR set multiplexor may be shared by some subsets of one or more banks (e.g., every two banks). Further, each bank may have multiple fuse CBR set multiplexors in order to increase a quantity of weak rows per bank that are serviced during a fuse CBR set refresh cycle.

In some examples, as a result of concurrent LORAR, a short tREF may be further decreased compared to global LORAR, while AddrRatio may be increased. Increasing AddrRatio may also lessen overhead attributed to fuse CBR set refresh cycles. For example, fuse CBR set refresh cycle overhead may be determined as a reciprocal of AddrRatio, and so by increasing AddrRatio, overhead may be decreased. Further, concurrent LORAR may be compatible with a relatively wide range of retention distributions (e.g., wider compared to global LORAR), while presenting potential die area savings. Concurrent LORAR may also allow multiple fuse-programmed CBR sets to be refreshed in parallel without increasing power and may support a reduced “steal” rate (e.g., rate of fuse CBR set refresh operations or cycles within a total quantity of CBR set operations). Concurrent LORAR may also reduce power by ignoring one or more row activations during refresh that may be omitted, as well as reduce routing congestion and a die size impact. Concurrent LORAR may also contribute to device scaling, as Fuse CBR set refresh efficiency may increase with a quantity of banks. Further, yield may be improved by further reducing a short tREF to allow additional weaker cells for use as weaker cell process characteristics may become acceptable to meet parameters in scaling. Concurrent LORAR may also apply to additional memory types (e.g., 3D memory, vertical channel transistor (VCT) DRAM, HBM due to distributed architecture). Additionally, or alternatively, similar benefits of global LORAR as described herein may be achieved using concurrent LORAR.

In some examples, an efficiency of fuse CBR set refresh operations may be quantified by how many weak rows are refreshed per fuse CBR set refresh cycle. For example, greater efficiency may indicate that less fuse CBR set refresh cycles are utilized to refresh all weak rows. In some cases, multiple weak rows may be refreshed in parallel due to CBR set compression (e.g., determined by compression of a global CBR counter). Further, global LORAR may be associated with a greater probability of improving efficiency based on CBR set compression with a greater likelihood that multiple weak rows fall on the same CBR, while concurrent LORAR may be associated with lower probability due to a lower likelihood that multiple weak rows may be with a same CBR set. In the case of concurrent LORAR, per-bank concurrency may be made available and may enable greater fuse CBR set refresh efficiency. In some cases, per-bank concurrency may indicate that multiple fuse CBR sets are refreshed in parallel by refreshing a fuse CBR set for every bank during each fuse CBR set refresh cycle. In some examples, a weak row may be refreshed per bank. In some cases, CBR set compression may be probabilistic while per-bank concurrency may be guaranteed, and thus, compared to global LORAR, concurrent LORAR may have a greater fuse CBR set efficiency (e.g., meaning that more weak rows are refreshed per fuse CBR Set Refresh cycle).

FIGS. 6A and 6B show examples of circuit diagrams 601 and 602 show examples of a circuit diagram 601 and a circuit diagram 602 that support retention aware refresh operations in accordance with examples as disclosed herein. One or more aspects of the circuit diagrams 601 and 602 may be implemented by one or more aspects of the system 100, the retention distribution chart 200, the flow diagram 300, and the circuit diagrams 400, 501, and 502. For example, the circuit diagram 601 may illustrate channel logic 505-c of circuitry 460-c including an address ratio logic 411-c, a refresh command counter 412-c, a rising edge detector 413-c, a comparator 420-c, a CBR counter 430-c, and a channel address multiplexor 450-c. The circuitry 460-c may be an example of circuitry 160 (e.g., in a memory system 110, in a memory system controller 140, in one or more memory devices 145, in one or more local controller 150, or in one or more memory arrays 155, or in a combination thereof). The circuit diagram 602 may illustrate bank logic 510-c of the circuitry 460-c, including bank logic 510-c-1 (e.g., an instance of bank logic) including a fuse CBR set multiplexor 441-b-1, a bank address multiplexor 550-c-1, a multiplexor 551-c-1, and a row address latch 552-c-1 (or other memory element). In some cases, FIGS. 6A and 6B may illustrate a second example of circuitry supporting a concurrent LORAR scheme as described herein.

In the example of FIG. 6A, the circuitry 460-c may support concurrent LORAR including a first example of a global fuse CBR set counter 440, such as a fuse CBR set counter 440-c. For example, instead of existing in every bank logic 510-c, such as in reference to the circuitry 460-b, a fuse CBR set counter 440-c may be located in the channel logic 505-b and may be a single instance of a global counter for all banks of a memory system including the circuitry 460-c (e.g., coupled similar as in global LORAR in FIG. 4). In some cases, if the fuse CBR set counter 440-c may be located in in a channel, the output FuseCbrSetCnt may be communicated to each bank logic 510-c. For example, a new bus may be added from the channel logic 505-c (e.g., from the channel) to each bank logic 510-c to directly route FuseCbrSetCnt to each bank. In the example of FIG. 6B, the bank logic 510-c-1 may receive FuseCbrSetCnt via the new bus into the fuse CBR set multiplexor 441-c-1, whereas FuscCbrSetRef may be input into the bank address multiplexor 550-c-1 and be based on REF and AddrSel. Additionally, or alternatively, such methods or functions may be performed using other circuitry in combination with, or alternative to, different multiplexors and/or counters described herein.

FIGS. 7A and 7B show examples of circuit diagrams 701 and 702 that support retention aware refresh operations in accordance with examples as disclosed herein. One or more aspects of the circuit diagrams 701 and 702 may be implemented by one or more aspects of the system 100, the retention distribution chart 200, the flow diagram 300, and the circuit diagrams 400, 501, 502, 601, and 602. For example, the circuit diagram 701 may illustrate channel logic 505-d of circuitry 460-d including an address ratio logic 411-d, a refresh command counter 412-d, a rising edge detector 413-d, a comparator 420-d, and a CBR counter 430-d. The circuit diagram 702 may illustrate bank logic 510-d of the circuitry 460-d, including bank logic 510-d-1 (e.g., an instance of bank logic) that may include a fuse CBR set multiplexor 441-d-1, a bank address multiplexor 550-d-1, a multiplexor 551-d-1, and a row address latch 552-d-1 (or other memory element). The circuitry 460-d may be an example of circuitry 160 (e.g., in a memory system 110, in a memory system controller 140, in one or more memory devices 145, in one or more local controller 150, or in one or more memory arrays 155, or in a combination thereof). In some cases, FIGS. 7A and 7B may illustrate a third example of circuitry supporting a concurrent LORAR scheme as described herein.

In the example of FIG. 7A, the circuitry 460-d may support concurrent LORAR including a second example of a global fuse CBR set counter 440, such as a fuse CBR set counter 440-d. In some examples, a global FuseCbrSetCnt signal may be communicated via a global row address bus at a beginning of a refresh cycle. For example, the channel logic 505-d may include an address multiplexor 450-d-1 and an address multiplexor 450-d-2 which may output a RowAddr signal (e.g., a new bus may be omitted). In such an example, the global row address bus, instead of communicating a global refresh address, may communicate a global FuseCbrSetCnt, which is used by each bank as an index to select a bank specific fuse CBR set refresh address to target weak rows.

For example, in the example of FIG. 7B, the bank logic 510-d-1 may include a fuse CBR set counter latch 753-d-1 that may include RowAddr and an AND logic operation of FuseCbrSetRef and a signal REXAL as inputs, and may output FuseCbrSetCnt to the fuse CBR Set multiplexor 441-d-1 to select a respective fuse CBR set. Additionally, or alternatively, another memory element may perform one or more functions of the fuse CBR set counter latch 753-d-1. Additionally, or alternatively, such methods or functions may be performed using other circuitry in combination with, or alternative to, different multiplexors and/or counters described herein. The bank logic 510-d-1 may also include circuitry 754-d-1 (e.g., a delay cell or an even string of inverters to delay REXAL) to output REXALdly from REXAL to the row address latch 552-d-1 (or another memory element). In some cases, REXALdly may ensure that FuseCbrSetCnt may be stored (e.g., latched) and that the updated fzBnkCbrSet has an opportunity to propagate to the latch 552-d-1 prior to the latch triggering. RowAddr may also be an input to the bank address multiplexor 550-d-1. In some instances, the associated memory system may include a multiplicity of latches (or a multiplicity of other memory elements). For example, the associated memory system may include a same quantity of latches as memory elements (e.g., a same quantity of latches as fuses) such that each latch may store a respective value (e.g., state) of each memory element.

In some examples, the circuitry 460 described with respect to FIGS. 1-7B may support simultaneous refresh operations. For example, a refresh command in a global LORAR system or a concurrent LORAR system (as illustrated in FIGS. 4-7B) may trigger both a normal refresh operation (e.g., a refresh operation for which a refresh address is derived from a CBR counter 430) in parallel with a fuse CBR set refresh operation (e.g., a refresh operation for which a refresh address is derived from a fuse CBR set counter 440 and fuse CBR set). In some examples, a refresh command may trigger refresh operations to occur in a multiplicity of banks, where one or more portions of the banks may use a refresh address that is derived from the CBR counter 430, while one or more other portions of banks may use a refresh address that is derived from one or more fuse CBR sets. Further, some examples may involve a refresh operation to a bank where a multiplicity of rows are refreshed. For example, some rows may be refreshed as a result of being addressed by a refresh address derived by the CBR counter 430, while other rows may be refreshed as a result of being addressed by a fuse CBR set. In some cases, performing multiple refresh operations in parallel for both normal refresh operations of CBR sets and refresh operations for fuse CBR sets may reduce refresh overhead and may increase refresh power. In some cases, performing multiple refresh operations in parallel for both normal refresh operations of CBR sets and refresh operations for fuse CBR sets may allow the tREF value 215-c to be lowered to a value closer to or equal to 215-a. Any quantity and combination of parallel refresh operations may also be considered.

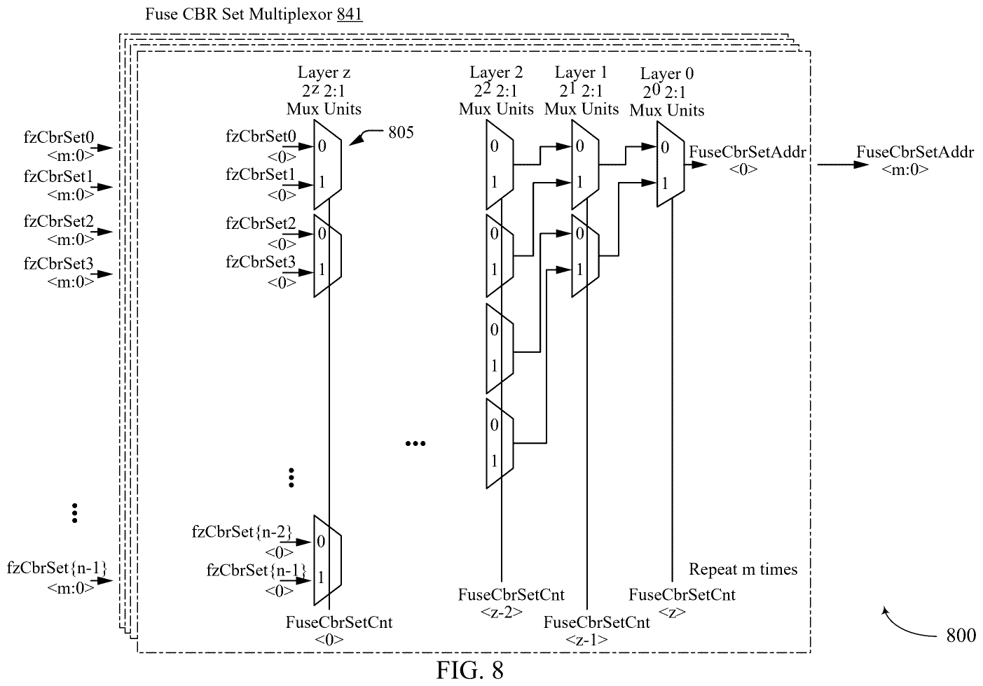

FIG. 8 shows an example of a circuit diagram 800 that supports retention aware refresh operations in accordance with examples as disclosed herein. One or more aspects of the circuit diagram 800 may be implemented by one or more aspects of the system 100, the retention distribution chart 200, the flow diagram 300, and the circuit diagrams 400, 501, 502, 601, 602, 701, and 702. For example, the circuit diagram 800 may illustrate a fuse CBR set multiplexor 841, which may represent a fuse CBR set multiplexor 441 as illustrated in FIGS. 4-7B. For example, the fuse CBR set multiplexor 841 may illustrate a global fuse CBR set multiplexor (e.g., the fuse CBR set multiplexor 441-a in global LORAR) or one instance of a bank-specific fuse CBR set multiplexor (e.g., one of the fuse CBR set multiplexors 441-b, 441-c, or 441-d).

In some examples, the fuse CBR set multiplexor 841 may include one or more layers of multiplexor units 805 (e.g., 2:1 multiplexor units) organized in a binary tree, including layers 0, 1, 2, through layer z. In some cases, there may be a total quantity of layers z+1. A quantity of multiplexor units 805 in each layer may decrease by a factor of 2. For example, a first layer (e.g., leftmost layer z) may be associated with 2^{z} multiplexor units 805, while a second layer may be associated with 2^{z-1} units. A final layer (e.g., layer 0) may be associated with 2⁰=1 multiplexor unit 805. In some cases, z may be equal to ┌log₂(n)−1┐. The multiplexor units 805 may be in some examples be 2:1 multiplexor units. For example, for inputs fzCbrSet0 (e.g., fzCbrSet<m:0>), fzCbrSet1, fzCbrSet2, fzCbrSet3, through fzCbrSet{n−1}, layer z multiplexor units 805 may each include two inputs of the addresses (e.g., with input <0>) and output one of the addresses based on a selection. This architecture may allow the fuse CBR set multiplexor 841 to output an address for a next fuse CBR set based on a fuse CBR counter value FuseCbrSetCnt, and may output a corresponding FuseCbrSetAddr, and may be selected to minimize loading on output nets and decrease total propagation delay through multiplexors. In some examples, the fuse CBR set multiplexor 841 may be repeated m+1 times for one instance each for <m:0>bits of a full address. In some cases, concurrent LOARAR may be associated with smaller multiplexors distributed on a per-bank basis and illustrated by FIG. 8. For example, a quantity of Fuse CBR Sets associated with each smaller multiplexor may be n per bank fuse sets. Additionally, or alternatively, methods or functions described herein with respect to different multiplexors and/or counters may be performed in combination with, or alternatively by, other circuitry.

In some examples, a die size impact of a LORAR scheme involving a multiplexor 841 may be at least partially quantified by a culminative die size impact of the components illustrated in FIG. 5A and 5B, as well as in FIGS. 6A-8 (e.g., fuses and fuse latches, FuseCbrSet multiplexor circuitry, AddrSel generation, CBR counter). The die size may also be impacted by die area associated with additional components (e.g., fuse latches, memory elements and other associated circuitry). In some examples, the AddrSel generation and CBR counter circuitry area may be identical for both global and concurrent LORAR. In some cases, if retention defects are randomly distributed across a die and excluding unlikely case of extremely high retention defects, one fuse programmed CBR set may cover one retention defect. Thus, to cover a same quantity of defects, a same quantity of fuses and fuse latches (e.g., including fuse CBR set addresses coupled with a fuse CBR set multiplexor 441) may be included for both global and concurrent LORAR. Therefore, an area may be identical between global and concurrent LORAR for fuses and fuse latches, AddrSel generation circuitry, and CBR counters.

Further, although an area of the FuseCbrSet multiplexor circuitry may vary, global LORAR may be associated with a single large global multiplexor, and a quantity of fuse CBR sets associated with the global multiplexor may be represented by n global. In some examples, a culminative area of the FuseCbrSet multiplexor circuitry in concurrent LORAR (or global LORAR, or both) may be proportional to the quantity of 2:1 multiplexor units. Further, a culminative area of a FuseCbrSet multiplexor for Concurrent LORAR may be less than or equal to that of global LORAR. For example, for Concurrent LORAR: FuseCbrSet Multiplexor Area Percent Reduction∝Banks∝1/n_{global}. Thus, a die size impact of Concurrent LORAR may be similar to, or less than, that of global LORAR for an equivalent quantity of fuse programmed CBR sets.

In some examples, the techniques described herein with respect to FIGS. 1-9B may provide for refresh addresses (e.g., CBR counter values, CBR sets, etc.) to be associated with memory elements to be refreshed at a faster rate. Additionally, or alternatively, various memory address space granularities may be associated with memory elements to be refreshed at a faster rate. For example, memory elements may be associated with one or more sets of row addresses, where the one or more sets of row addresses may be greater than a refresh address set granularity, or less than a refresh address set granularity (e.g., a single row). Further, fuse programming may involve fuse programming rows that may be more susceptible to row hammer. For example, such rows may experience refresh at a faster rate, which may allow a row hammer mitigation threshold to be increased, reducing a bandwidth required for RHR, and further allowing for reduced refresh overhead or enabling memory technologies more susceptible to row hammer. Additionally, or alternatively, fuse programming of rows to be refreshed at a faster rate may represent an alternative method to row repairs used to resolve retention related issues, which may in some cases provide die area savings.

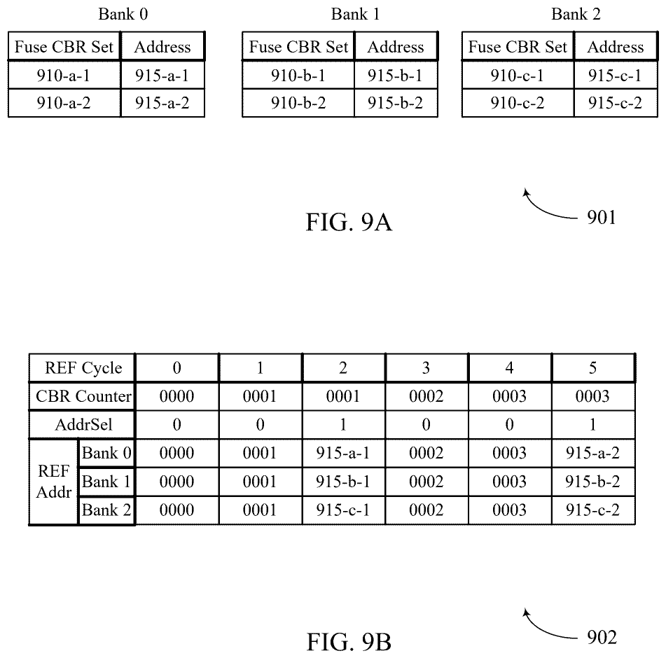

FIGS. 9A and 9B show examples of an bank address diagram 901 and a refresh assignment diagram 902 that support retention aware refresh operations in accordance with examples as disclosed herein. One or more aspects of the bank address diagram 901 and the refresh assignment diagram 902 may be implemented by one or more aspects of the system 100, the retention distribution chart 200, the flow diagram 300, and the circuit diagrams 400, 501, 502, 601, 602, 701, 702, and 800. For example, the bank address diagram 901 and the refresh assignment diagram 902 may illustrate assignment of addresses 915 to fuse CBR sets 910 of a memory system, such as a memory system 110, for supporting selection of a next CBR set or a next fuse CBR set for a refresh operation using a ratio AddrRatio as discussed herein. In some examples, the bank address diagram 901 and the refresh assignment diagram 902 may illustrate aspects of a concurrent LORAR scheme as described herein.

In the example of FIG. 9A, three example banks may include bank 0, bank 1, and bank 2, where each bank may include multiple fuse CBR sets 910 with corresponding addresses 915. For example, the bank 0 may include a fuse CBR set 910-a-1 with an address 915-a-1 and a fuse CBR set 910-a-2 with an address 915-a-2. The bank 1 may include a fuse CBR set 910-b-1 with an address 915-b-1 and a fuse CBR set 910-b-2 with an address 915-b-2, and the bank 2 may include a fuse CBR set 910-c-1 with an address 915-c-1 and a fuse CBR set 910-c-2 with an address 915-c-2. In the example of FIG. 9B, a refresh address may be used for each bank for several sequential refresh cycles. In some cases, a single refresh cycle may refer to all banks on a die receiving a refresh, or one or more per-bank refresh operations may be performed. In some cases, the refreshes described with respect to FIG. 9B may use a concurrent LORAR scheme, with an AddrRatio value of 3. For example, in a first refresh cycle 0, a CBR counter may be 0000 (e.g., 0000 in hexadecimal), AddrSel may be 0, and banks 0-2 may each refresh a local bank address 0000.

A second refresh cycle 1 may involve an incremented CBR counter as AddrRatio may not yet equal a refresh command counter value (as every third refresh may be a fuse CBR set refresh). Thus, the refresh cycle 1 may involve a CBR counter value of 1, an AddrSel value of 0, and respective addresses of 0001 for each bank. In a third refresh cycle 2,the refresh operation may be “stolen,” or used for a fuse CBR set refresh across all banks. In such an example, the banks 0-2 may each refresh a first fuse CBR set 910-a-1, 910-b-1, and 910-c-1 at corresponding addresses 915-a-1, 915-b-1, and 915-c-1, where the addresses may be at any point relative to one another (e.g., may not be adjacent like regular CBR sets associated with the CBR counter, or may be adjacent and incremented linearly, for example, if PRAC is supported). The CBR counter may remain at 0001 as the refresh operation may be a fuse CBR set refresh operation.

In some cases, the process described herein may repeat with the CBR counter incrementing based on the conditions described herein with respect to FIGS. 1-9 (e.g., may increment for non-fuse CBR set refresh operations when AddrSel=0), which may reset at restart or power off. Fuse CBR counter(s) may also increment as described herein with respect to FIGS. 1-9 through fuse CBR sets (e.g., may increment for fuse CBR set refresh when AddrSel=1). In some cases, CBR counter(s) may increment based on the AddrRatio value of 3 in examples illustrated in FIGS. 9A and 9B. For example, refresh operations 3 and 4 may involve a CBR counter incrementing to 0002 and 0003 for AddrSel of 0 and 0 and addresses 0002 and 0003, while a fifth refresh cycle 5 may involve the same CBR counter value of 0003 with respective addresses 915-a-2, 915-b-2, and 915-c-2 of fuse CBR sets for refresh.

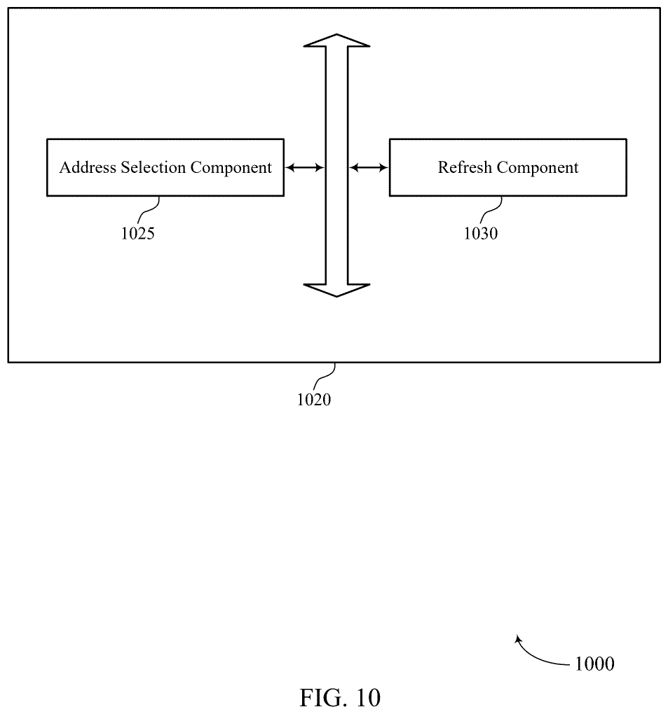

FIG. 10 shows a block diagram 1000 of a memory system 1020 that supports retention aware refresh operations in accordance with examples as disclosed herein. The memory system 1020 may be an example of aspects of a memory system as described with reference to FIGS. 1 through 9. The memory system 1020, or various components thereof, may be an example of means for performing various aspects of retention aware refresh operations as described herein. For example, the memory system 1020 may include an address selection component 1025 a refresh component 1030, or any combination thereof. Each of these components, or components of subcomponents thereof (e.g., one or more processors, one or more memories), may communicate, directly or indirectly, with one another (e.g., via one or more buses).

The address selection component 1025 may be configured as or otherwise support a means for selecting a first address associated with a first set of memory cells for a first refresh operation based at least in part on a first address select value and a value of a first counter. The refresh component 1030 may be configured as or otherwise support a means for refreshing the first set of memory cells based at least in part on selecting the first address. In some examples, the address selection component 1025 may be configured as or otherwise support a means for selecting a second address associated with a second set of memory cells for a second refresh operation based at least in part on a second address select value and a value of a second counter, where the second set of memory cells is associated with a set of memory elements. In some examples, the refresh component 1030 may be configured as or otherwise support a means for refreshing the second set of memory cells based at least in part on selecting the second address.

In some examples, the described functionality of the memory system 1020, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 1020, or various components thereof, may be implemented at least in part by instructions (e.g., stored in memory, non-transitory computer-readable medium) executable by such at least one processor.

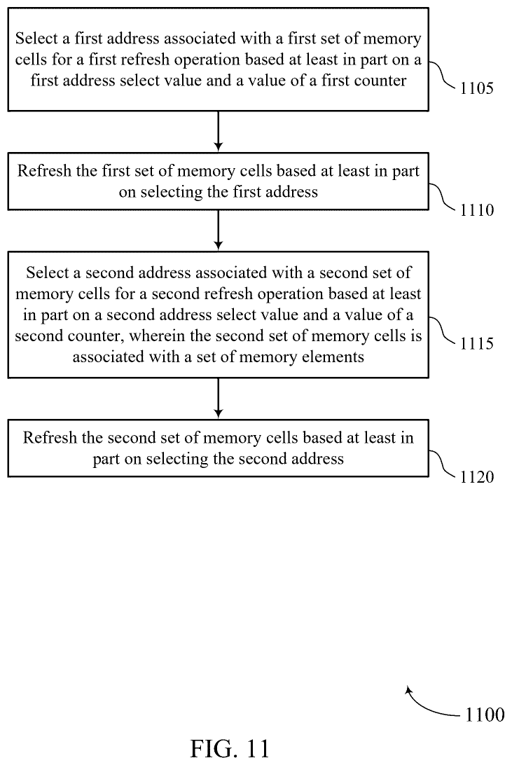

FIG. 11 shows a flowchart illustrating a method 1100 that supports retention aware refresh operations in accordance with examples as disclosed herein. The operations of method 1100 may be implemented by a memory system or its components as described herein. For example, the operations of method 1100 may be performed by a memory system as described with reference to FIGS. 1 through 10. In some examples, a memory system may execute a set of instructions to control the functional elements of the device to perform the described functions. Additionally, or alternatively, the memory system may perform aspects of the described functions using special-purpose hardware.

At 1105, the method may include selecting a first address associated with a first set of memory cells for a first refresh operation based at least in part on a first address select value and a value of a first counter. In some examples, aspects of the operations of 1105 may be performed by an address selection component 1025 as described with reference to FIG. 10.

At 1110, the method may include refreshing the first set of memory cells based at least in part on selecting the first address. In some examples, aspects of the operations of 1110 may be performed by a refresh component 1030 as described with reference to FIG. 10.

At 1115, the method may include selecting a second address associated with a second set of memory cells for a second refresh operation based at least in part on a second address select value and a value of a second counter, where the second set of memory cells is associated with a set of memory elements. In some examples, aspects of the operations of 1115 may be performed by an address selection component 1025 as described with reference to FIG. 10.

At 1120, the method may include refreshing the second set of memory cells based at least in part on selecting the second address. In some examples, aspects of the operations of 1120 may be performed by a refresh component 1030 as described with reference to FIG. 10.

In some examples, an apparatus as described herein may perform a method or methods, such as the method 1100. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for selecting a first address associated with a first set of memory cells for a first refresh operation based at least in part on a first address select value and a value of a first counter; refreshing the first set of memory cells based at least in part on selecting the first address; selecting a second address associated with a second set of memory cells for a second refresh operation based at least in part on a second address select value and a value of a second counter, where the second set of memory cells is associated with a set of memory elements; and refreshing the second set of memory cells based at least in part on selecting the second address.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 2: An apparatus, including: a memory array including a first set of memory cells and a second set of memory cells, where the second set of memory cells is associated with a set of memory elements; a first counter associated with the first set of memory cells and the second set of memory cells, where each value of the first counter corresponds to a subset of the first set of memory cells, a subset of the second set of memory cells, or both; a second counter associated with the second set of memory cells, where a value of the second counter corresponds to at least the subset of the second set of memory cells; a memory element selection component coupled with the second counter, the memory element selection component configured to select at least the subset of the second set of memory cells based at least in part on the value of the second counter; and an address selection component coupled with the first counter and the memory element selection component, the address selection component configured to select a first address output by the first counter for a first refresh operation based at least in part on a first address select value, or to select a second address output by the memory element selection component for a second refresh operation based at least in part on a second address select value.

Aspect 3: The apparatus of aspect 2, including: address select value generation circuitry, including: a third counter associated with a quantity of refresh operations; and comparison circuitry coupled with the first counter, the second counter, the third counter, and the address selection component, the comparison circuitry configured to compare the value of the third counter with a threshold value and to output the first address select value based at least in part on the value of the third counter failing to satisfy the threshold value, or to output the second address select value based at least in part on the value of the third counter satisfying the threshold value, where the first address select value includes a first voltage value and the second address select value includes a second voltage value.

Aspect 4: The apparatus of aspect 3, where the third counter is configured to be incremented after the first refresh operation based at least in part on the first address select value, or to be reset after the second refresh operation based at least in part on the second address select value.

Aspect 5: The apparatus of any of aspects 3 through 4, where the threshold value includes a threshold quantity of refresh operations that is based at least in part on a ratio of one or more first refresh operations associated with the first counter and one or more second refresh operations associated with the second counter.

Aspect 6: The apparatus of any of aspects 2 through 5, where the first counter is configured to be incremented after the first refresh operation based at least in part on selecting the first address, or the second counter is configured to be incremented after the second refresh operation based at least in part on selecting the second address.

Aspect 7: The apparatus of any of aspects 2 through 6, further including: a fourth counter associated with each row of the first set of memory cells and each row of the second set of memory cells, where the fourth counter is configured to be reset based at least in part on selecting the first address and maintain an unadjusted value based at least in part on selecting the second address.

Aspect 8: The apparatus of any of aspects 2 through 7, where the second refresh operation is configured to be performed between one or more array boundaries of the first counter based at least in part on selecting the second address.

Aspect 9: The apparatus of any of aspects 2 through 8, where the subset of the second set of memory cells is included in a group of subsets of second sets of memory cells, each subset of second sets of memory cells is associated with a respective set of memory elements, and the group corresponds to a refresh period range.

Aspect 10: The apparatus of any of aspects 2 through 9, where a total quantity of memory elements of the set of memory elements is based at least in part on a quantity of rows of memory cells of the second set of memory cells.

Aspect 11: The apparatus of any of aspects 2 through 10, where the first set of memory cells is associated with a first refresh period and the second set of memory cells is associated with a second refresh period.

Aspect 12: The apparatus of any of aspects 2 through 11, where a first charge retention duration associated with the first set of memory cells is greater than a second charge retention duration associated with the second set of memory cells.

Aspect 13: The apparatus of any of aspects 2 through 12, where the memory element selection component includes: a plurality of second memory elements (e.g., latches, or fuses or other memory elements) storing a state of one or more memory elements (e.g., fuses, or latches or other memory elements) associated with the second address; and a multiplexing component configured to select the second address.

An apparatus is described. The following provides an overview of aspects of the apparatus as described herein:

Aspect 14: An apparatus, including: a memory array including a first set of memory cells and a plurality of second sets of memory cells, where each second set of memory cells is associated with a subset of memory cells of the memory array and is associated with a respective set of memory elements; a first counter associated with the first set of memory cells and the plurality of second sets of memory cells, where each value of the first counter corresponds to a subset of the first set of memory cells, a subset of memory cells of the second sets of memory cells, or both; one or more second counters associated with the plurality of second sets of memory cells; a plurality of memory element selection components that are each coupled with a respective second counter and associated with a respective second set of memory cells, each memory element selection component configured to select a respective subset of the second set of memory cells based at least in part on a value of the respective second counter; and a plurality of address selection components coupled with the first counter and one or more of the plurality of memory element selection components, the plurality of address selection components each configured to select a first address output by the first counter for a first refresh operation based at least in part on a first address select value, or to select a respective second address output by a respective memory element selection component for a second refresh operation based at least in part on a second address select value.

Aspect 15: The apparatus of aspect 14, including: address select value generation circuitry, including: a third counter associated with a quantity of refresh operations; and comparison circuitry coupled with the first counter, the one or more second counters, the third counter, and the plurality of address selection components, the comparison circuitry configured to compare the value of the third counter with a threshold value and to output the first address select value based at least in part on the value of the third counter failing to satisfy the threshold value, or to output the second address select value based at least in part on the value of the third counter satisfying the threshold value, where the first address select value includes a first voltage value and the second address select value includes a second voltage value.

Aspect 16: The apparatus of aspect 15, where the third counter is configured to be incremented after the first refresh operation based at least in part on the first address select value, or to be reset after the second refresh operation based at least in part on the second address select value.

Aspect 17: The apparatus of any of aspects 15 through 16, where the threshold value includes a threshold quantity of refresh operations that is based at least in part on a ratio of one or more first refresh operations associated with the first counter and one or more second refresh operations associated with the one or more second counters.

Aspect 18: The apparatus of any of aspects 14 through 17, where each memory element selection component of the plurality of memory element selection components includes: a plurality of second memory elements (e.g., latches, or fuses or other memory elements) storing a state of one or more memory elements (e.g., fuses, or latches or other memory elements), associated with the respective second address; and a multiplexing component configured to select the respective second address.

Aspect 19: The apparatus of aspect 18, where each memory element selection component further includes: a respective second counter of the one or more second counters.

Aspect 20: The apparatus of any of aspects 18 through 19, where each memory element selection component of the plurality of memory element selection components is coupled with a same second counter of the one or more second counters.

Aspect 21: The apparatus of any of aspects 18 through 20, where each memory element selection component is coupled with a subset of a plurality of rows of the memory array.

An apparatus is described. The following provides an overview of aspects of the apparatus as described herein:

Aspect 22: An apparatus, including: a memory array including a first set of memory cells and a second set of memory cells, where the second set of memory cells is associated with a set of memory elements; a first refresh counter associated with the first set of memory cells and the second set of memory cells, the first refresh counter for incrementing through memory cells of the first set of memory cells and the second set of memory cells, where a value of the first refresh counter is configured to be adjusted based at least in part on a first address select signal; a second refresh counter associated with the second set of memory cells, the second refresh counter for incrementing through memory cells of the second set of memory cells, where a value of the second refresh counter is configured to be adjusted based at least in part on a second address select signal; and a first multiplexor coupled with the first refresh counter and the second refresh counter, the first multiplexor configured to select a first address output by the first refresh counter for a first refresh operation associated with the first set of memory cells, or to select a second address output by the second refresh counter for a second refresh operation associated with the second set of memory cells.

Aspect 23: The apparatus of aspect 22, where the first refresh counter linearly increments through memory cells of the first set of memory cells and the second set of memory cells.

Aspect 24: The apparatus of any of aspects 22 through 23, further including: a third counter for counting a quantity of refresh operations performed on the first set of memory cells and the second set of memory cells; and a comparator coupled with the first refresh counter, the second refresh counter, and the third counter, where the comparator is configured to output the second address select signal based at least in part on a value of the third counter satisfying a threshold value and output the first address select signal based at least in part on a value of the third counter failing to satisfy the threshold value.

Aspect 25: The apparatus of aspect 24, where the threshold value is based at least in part on a ratio of first refresh operations to second refresh operations performed.

Aspect 26: The apparatus of any of aspects 24 through 25, where the third counter is configured to be adjusted after the first refresh operation is performed and to be reset after the second refresh operation is performed.

Aspect 27: The apparatus of any of aspects 22 through 26, where the first refresh counter is configured to be adjusted after the first refresh operation is performed and the second refresh counter is configured to be adjusted after the second refresh operation is performed.

Aspect 28: The apparatus of any of aspects 22 through 27, further including: a second multiplexor coupled with the second refresh counter, where the second multiplexor is configured to select a subset of the second set of memory cells based at least in part on the value of the second refresh counter.

Aspect 29: The apparatus of any of aspects 22 through 28, where each memory cell of the second set of memory cells is associated with a plurality of memory elements.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a memory array comprising a first set of memory cells and a second set of memory cells, wherein the second set of memory cells is associated with a set of memory elements;
a first counter associated with the first set of memory cells and the second set of memory cells, wherein each value of the first counter corresponds to a subset of the first set of memory cells, a subset of the second set of memory cells, or both;
a second counter associated with the second set of memory cells, wherein a value of the second counter corresponds to at least the subset of the second set of memory cells;
a memory element selection component coupled with the second counter, the memory element selection component configured to select at least the subset of the second set of memory cells based at least in part on the value of the second counter; and
an address selection component coupled with the first counter and the memory element selection component, the address selection component configured to select a first address output by the first counter for a first refresh operation based at least in part on a first address select value, or to select a second address output by the memory element selection component for a second refresh operation based at least in part on a second address select value.

2. The apparatus of claim 1, comprising:
address select value generation circuitry, comprising:
a third counter associated with a quantity of refresh operations; and
comparison circuitry coupled with the first counter, the second counter, the third counter, and the address selection component, the comparison circuitry configured to compare the value of the third counter with a threshold value and to output the first address select value based at least in part on the value of the third counter failing to satisfy the threshold value, or to output the second address select value based at least in part on the value of the third counter satisfying the threshold value, wherein the first address select value comprises a first voltage value and the second address select value comprises a second voltage value.

3. The apparatus of claim 2, wherein the third counter is configured to be incremented after the first refresh operation based at least in part on the first address select value, or to be reset after the second refresh operation based at least in part on the second address select value.

4. The apparatus of claim 2, wherein the threshold value comprises a threshold quantity of refresh operations that is based at least in part on a ratio of one or more first refresh operations associated with the first counter and one or more second refresh operations associated with the second counter.

5. The apparatus of claim 1, wherein:
the first counter is configured to be incremented after the first refresh operation based at least in part on selecting the first address, or
the second counter is configured to be incremented after the second refresh operation based at least in part on selecting the second address.

6. The apparatus of claim 1, further comprising:
a fourth counter associated with each row of the first set of memory cells and each row of the second set of memory cells, wherein the fourth counter is configured to be reset based at least in part on selecting the first address; and
maintain an unadjusted value based at least in part on selecting the second address.

7. The apparatus of claim 1, wherein the second refresh operation is configured to be performed between one or more array boundaries of the first counter based at least in part on selecting the second address.

8. The apparatus of claim 1, wherein:
the subset of the second set of memory cells is included in a group of subsets of second sets of memory cells,
each subset of second sets of memory cells is associated with a respective set of memory elements, and
the group corresponds to a refresh period range.

9. The apparatus of claim 1, wherein a total quantity of memory elements of the set of memory elements is based at least in part on a quantity of rows of memory cells of the second set of memory cells.

10. The apparatus of claim 1, wherein the first set of memory cells is associated with a first refresh period and the second set of memory cells is associated with a second refresh period.

11. The apparatus of claim 1, wherein a first charge retention duration associated with the first set of memory cells is greater than a second charge retention duration associated with the second set of memory cells.

12. The apparatus of claim 1, wherein the memory element selection component comprises:
a plurality of second memory elements storing a state of one or more memory elements associated with the second address; and
a multiplexing component configured to select the second address.

13. An apparatus, comprising:
a memory array comprising a first set of memory cells and a plurality of second sets of memory cells, wherein each second set of memory cells is associated with a subset of memory cells of the memory array and is associated with a respective set of memory elements;
a first counter associated with the first set of memory cells and the plurality of second sets of memory cells, wherein each value of the first counter corresponds to a subset of the first set of memory cells, a subset of memory cells of the plurality of second sets of memory cells, or both;
one or more second counters associated with the plurality of second sets of memory cells;
a plurality of memory element selection components that are each coupled with a respective second counter and associated with a respective second set of memory cells, each memory element selection component configured to select a respective subset of the respective second set of memory cells based at least in part on a value of the respective second counter; and
a plurality of address selection components coupled with the first counter and one or more of the plurality of memory element selection components, the plurality of address selection components each configured to select a first address output by the first counter for a first refresh operation based at least in part on a first address select value, or to select a respective second address output by a respective memory element selection component for a second refresh operation based at least in part on a second address select value.

14. The apparatus of claim 13, comprising:
address select value generation circuitry, comprising:
a third counter associated with a quantity of refresh operations; and
comparison circuitry coupled with the first counter, the one or more second counters, the third counter, and the plurality of address selection components, the comparison circuitry configured to compare the value of the third counter with a threshold value and to output the first address select value based at least in part on the value of the third counter failing to satisfy the threshold value, or to output the second address select value based at least in part on the value of the third counter satisfying the threshold value, wherein the first address select value comprises a first voltage value and the second address select value comprises a second voltage value.

15. The apparatus of claim 14, wherein the third counter is configured to be incremented after the first refresh operation based at least in part on the first address select value, or to be reset after the second refresh operation based at least in part on the second address select value.

16. The apparatus of claim 14, wherein the threshold value comprises a threshold quantity of refresh operations that is based at least in part on a ratio of one or more first refresh operations associated with the first counter and one or more second refresh operations associated with the one or more second counters.

17. The apparatus of claim 13, wherein each memory element selection component of the plurality of memory element selection components comprises:
a plurality of second memory elements storing a state of one or more memory elements, associated with the respective second address; and
a multiplexing component configured to select the respective second address.

18. The apparatus of claim 17, wherein each memory element selection component further comprises:
a respective second counter of the one or more second counters.

19. The apparatus of claim 17, wherein each memory element selection component of the plurality of memory element selection components is coupled with a same second counter of the one or more second counters.

20. A method by a memory system, comprising:
selecting a first address associated with a first set of memory cells for a first refresh operation based at least in part on a first address select value and a value of a first counter;
refreshing the first set of memory cells based at least in part on selecting the first address;
selecting a second address associated with a second set of memory cells for a second refresh operation based at least in part on a second address select value and a value of a second counter, wherein the second set of memory cells is associated with a set of memory elements; and
refreshing the second set of memory cells based at least in part on selecting the second address.
